(19) United States
(12) Patent Application Publication
(10) Pub. No.: US 2025/0271779 A1
(43) Pub. Date: Aug. 28, 2025

(54) MODELING SUBSTRATE CHARACTERISTICS FROM MANUFACTURING SENSOR DATA

(71) Applicant: Applied Materials, Inc., Santa Clara, CA (US)

(72) Inventors: Chao Liu, Singapore (SG); Yudong Hao, Fremont, CA (US); Hanyou Chu, Palo Alto, CA (US)

(21) Appl. No.: 18/590,069

(22) Filed: Feb. 28, 2024

(51) Int. Cl. G03F 7/00

(52) U.S. Cl. CPC G03F 7/706845; G03F 7/706839

(57) ABSTRACT

A method for estimating process characteristics is provided. The method can include collecting process data from a spectral emitter and a spectral sensor during a substrate processing operation, and generating a calibrated model for the process data. Generating a calibrated model can include selecting a calibration option from a set of calibration options, based on a degree of freedom associated with a given calibration option, and calibrating a base model to generate the calibrated model. The base model is calibrated using the selected calibration option and a portion of the first process data.

### TECHNICAL FIELD

The instant specification relates to systems and methods for estimating substrate characteristic from manufacturing sensor data. More specifically, the instant specification relates to analysis of multivariate sensor data to generate an indication of evolution of substrate processing parameters through a duration of a processing operation.

### BACKGROUND

Optical critical dimension (OCD) metrology is a technique employed to model and extract substrate characteristics (e.g., critical dimensions) from spectral data captured from a substrate within semiconductor manufacturing. This method uses specialized optical emitters, such as broadband light source or multiple LEDs, to shine light onto the surface of a substrate during or between manufacturing operations. The emitted light interacts with the substrate, and its reflected or diffracted light is directed to a sensor where its properties are measured and recorded. This sensed, spectral data is then analyzed to determine substrate characteristics. These substrate characteristics can include layer thicknesses, critical dimensions, profiles of microscopic features, optical constants of materials on the substrate, etc.

### SUMMARY

The following is a simplified summary of the disclosure in order to provide a basic understanding of some aspects of the disclosure. This summary is not an extensive overview of the disclosure. It is intended to neither identify key or critical elements of the disclosure, nor delineate any scope of the particular implementations of the disclosure or any scope of the claims. Its sole purpose is to present some concepts of the disclosure in a simplified form as a prelude to the more detailed description that is presented later.

In some embodiments of the present disclosure, a method is provided. The method includes obtaining several sets of process data for a sample, each set of the process data associated with a respective time of several times of a sample processing operation, and selecting a calibration engine from several calibration engines. In some aspects, the several calibration engines include at least a temporal calibration engine that calibrates a joint model having one or more fitting parameters characterizing evolution of one or more sample properties across the several times, and a multi-model calibration engine that calibrates several models, each model of the several models characterizing the one or more sample properties for a respective time of the several times. In some aspects, individual models of the several models are calibrated using multiple sets of the process data of the several sets of process data. The method further includes, applying the selected calibration engine to the several sets of the process data to calibrate one or more models for the process data, identifying, using the one or more calibrated models, the one or more sample properties, and generating, in view of the one or more identified sample properties, an indication of conformity of the processing operation to a target specification.

In some embodiments of the present disclosure, a system is provided. In embodiments, the system includes memory and a processing device coupled to the memory. In embodiments, the processing device is to obtain several sets of process data for a sample, each set of the process data associated with a respective time of several times of a sample processing operation, and select a calibration engine from several calibration engines. In some aspects, several calibration engines include at least a temporal calibration engine that calibrates a joint model having one or more fitting parameters characterizing evolution of one or more sample properties across the several times, and a multi-model calibration engine that calibrates several models, each model of the several models characterizing the one or more sample properties for a respective time of the several times. In some aspects, individual models of the several models are calibrated using multiple sets of the process data of the several sets of process data. In some aspects, the processing device is to further, apply the selected calibration engine to the several sets of the process data to calibrate one or more models for the process data, identify, using the one or more calibrated models, the one or more sample properties, and generate, in view of the one or more identified sample properties, an indication of conformity of the processing operation to a target specification.

In some embodiments of the present disclosure, a non-transitory computer readable storage medium is provided. In some aspects, the non-transitory computer readable storage medium can include instructions that, when executed by a processing device, causes the processing device to perform operations including obtaining several sets of process data for a sample, each set of the process data associated with a respective time of several times of a sample processing operation, and selecting a calibration engine from several calibration engines. In some aspects, the several of calibration engines include at least a temporal calibration engine that calibrates a joint model having one or more fitting parameters characterizing evolution of one or more sample properties across the several times, and a multi-model calibration engine that calibrates several models, each model of the several models characterizing the one or more sample properties for a respective time of the several times. In some aspects, individual models of the several models are calibrated using multiple sets of the process data of the several sets of process data. In some aspects, the operations further include applying the selected calibration engine to the several sets of the process data to calibrate one or more models for the process data, identifying, using the one or more calibrated models, the one or more sample properties, and generating, in view of the one or more identified sample properties, an indication of conformity of the processing operation to a target specification.

### BRIEF DESCRIPTION OF THE DRAWINGS

The present disclosure is illustrated by way of example, and not by way of limitation in the figures of the accompanying drawings.

FIG. 1 illustrates an example system architecture capable of supporting a predictive module and a process model for generating optical critical dimension (OCD) inferences, according to some embodiments of the present disclosure.

FIG. 2A illustrates an example process for generating the process model of FIG. 1, according to some embodiments of the present disclosure.

FIG. 2B illustrates an example data structure of the process data of FIG. 2A, according to some embodiments of the present disclosure.

FIG. 2C illustrates an example process for generating substrate characteristic inferences with the process model of FIG. 2A, according to some embodiments of the present disclosure.

FIG. 3A illustrates an example model selection subprocess of FIG. 2A, according to some embodiments of the present disclosure.

FIG. 3B illustrates example information influencing the model selection subprocess of FIGS. 2A and 3A, according to some embodiments of the present disclosure.

FIG. 3C illustrates an example calibration strategy selection subprocess of FIG. 2A, according to some embodiments of the present disclosure.

FIG. 4 illustrates an example multi-model calibration with regularization strategy of FIG. 3C, according to some embodiments of the present disclosure.

FIG. 5 illustrates an example multi-model co-optimization calibration strategy of FIG. 3C, according to some embodiments of the present disclosure.

FIG. 6 illustrates an example spatial-temporal calibration strategy of FIG. 3C, according to some embodiments of the present disclosure.

FIG. 7 illustrates a flow diagram of an example method for generating substrate parameter inferences from manufacturing sensor data, according to some embodiments of the present disclosure.

FIG. 8 illustrates a block diagram of an example processing device operating in accordance with one or more aspects of the present disclosure.

### DETAILED DESCRIPTION

To extract substrate characteristic data from the collected spectral data, first, a physical model is often made to describe the substrate characteristics, and a set of model parameters representing those substrate characteristics are determined. Second, an electromagnetic solver is used to theoretically simulate a signal generated when the incoming light interacts with the substrate, as described by the physical model. Finally, a mathematical optimization process or, specifically, a nonlinear least square regression algorithm iteratively adjusts the physical model parameters to achieve the best fit of the simulated signal to the measured signal, at which point the physical model parameters are reported as the inferred substrate characteristics.

The physical model to represent the substrate may be any model that includes a comprehensive set of parameters, which may be reflective of substrate characteristics. For example, a single model parameter of the physical model may correspond to the depth of a layer of the substrate, the width of a channel, a microscopic surface feature of a substrate, the rate of change in any of these, or other critical dimensions, and so on and so forth. These parameters may be constant, time-dependent, and/or dependent on several factors present within a manufacturing operation.

Alternatively, the electromagnetic solver can be replaced by a mathematical model, such as a statistical or machine learning model. This mathematical model is typically calibrated through a training process with simulated or experimental data e.g., (from an electromagnetic solver or a similar optimization or calibration process). During calibration and inference using such a mathematical model, parameters reflective of the substrate characteristics (e.g., from the physical model) may be combined with known variables (e.g., inputs such as time, or emissions data) to produce simulated spectral data (e.g., outputs). In such a way, the mathematical model may simulate the influence of a substrate and substrate characteristics on the known inputs during a manufacturing operation.

Calibrating a model to manufacturing process data (at times herein referred to as “training,” “fitting,” or “optimizing”) is a process employing one of many possible strategies. Calibration may adjust the parameters of the mathematical model so that the model produces accurate outputs. In this way, calibration intakes the process dataset and a base, uncalibrated model, to produce a calibrated model. Once a mathematical model has been (sufficiently) calibrated, the model parameters may be accurate parameters from which inference of substrate characteristics and/or their evolution, during a process, may be derived. Thus, substrate characteristics throughout a manufacturing operation can be inferred through use of a calibration process, a mathematical model, and a set of experimental data gathered during the manufacturing process.

In some cases, application of the model to infer substrate characteristics may be performed in-situ, or during a subsequent manufacturing operation. This can be referred to as “in-situ OCD inference” and can be used to non-invasively monitor substrate characteristics as a manufacturing operation is ongoing. In-situ OCD inference may provide a detailed picture of temporal evolution of in-chamber parameters otherwise difficult to determine. For example, time-independent analyses may report on etch depth at each time step, and an etch rate can be inferred based on tracking the temporal evolution of the etch depth over the duration of a processing operation. In-situ OCD inference may report directly on both etch rate and etch depth, e.g., by utilizing a mathematical model that characterizes temporal evolution of spectral data from a substrate as etch depth increases.

When possible, in-situ OCD inference can thus provide rapid access to sensed conditions and substrate characteristics and include implementation in situations that might otherwise be too cumbersome or invasive to generate measurements (e.g., during a plasma-based manufacturing operation). In-situ OCD inference can further provide increases in precision, accuracy, efficiency of process learning (e.g., understanding newly designed processing recipes, updating processing recipes for new applications, etc.). Thus, should in-situ OCD inference be implemented to be sufficiently fast, accurate, and reliable, such inference techniques may be leveraged to enable enhanced insight into manufacturing operations and process learning, improved remediation abilities and performance regulation, and advanced increases in yield and quality of finished product.

Applying OCD inference in-situ can be challenging. To begin with, traditional methods may be overly rigid or lacking in versatility and mutability in applications. This may be evident when applying calibration within OCD inference, which traditionally includes making two major decisions. First, the type of mathematical model to be used is selected, then the calibration (i.e., fitting) strategy is determined. In practice, these can be intimately tied and are often accomplished concurrently.

Aspects and embodiments of the present disclosure provide for systems and methods enabling a wide range of calibration (fitting) techniques that support models with flexible number of degrees of freedom (number of fitting parameters). Calibration techniques with a relatively low number of fitting parameters (e.g., temporal calibration) are suitable to characterizing technological processes with a high degree of predictability, well-understood (physical and/or chemical) dynamics, and/or situations where limited data is available. Calibration techniques with a relatively high number of fitting parameters (e.g., frame-wise calibration) are suitable to characterizing operations with a high degree of variability, less understood dynamics and interdependencies, and/or situations where the data is rich and diverse. Temporal calibration employs a single mathematical model d(λ, t; {p}) to fit the measured data d (e.g., spectral data, such as reflectance R(λ)) as a function of both time t and one or more variables λ (e.g., wavelength) that can be controlled during a measurement and/or manufacturing operation. The model can have any suitable set {p}=p₁, p₂, . . . , of floating parameters, e.g., thickness, depth, width, etc., of various manufactured features, chemical composition, and/or any properties of a sample that undergoes a sample processing operation. Temporal calibration can presume some knowledge about how the fitting parameters {p} change with time. In this technique, the process behavior is represented, based on prior knowledge, as one or multiple mathematical functions p(t) over time t, such as linear, piece-wise linear, and/or nonlinear functions, e.g., polynomial functions, power-law functions, exponential functions, sigmoid functions, and/or the like. For example, the process behavior may be modeled with a linear (or affine) dependence of a height of the deposited film, p₁(t)=at+b, with fitting constants a and b to be determined using one or more fitting algorithms. Process behavior can similarly be modeled for other floating parameters p₂, p₃, . . . (the model functions can be different for different floating parameters). The temporal calibration method attempts to fit all frames tⱼ of data (e.g., optical inspection data collected at time tⱼ) using a single model d(λ, t; {p(t)}) and can be efficient when data is sparse and/or have a low variability.

Frame-wise calibration attempts to fit multiple sets of data, e.g., frames tⱼ, using a composite model formed from multiple individual “frame models,” each frame model dⱼ(λ; {p}ⱼ) corresponding to a respective frame of the process data. The frame-wise calibration captures and characterizes “snapshots” of the substrate's characteristics as time passes. The floating parameters {p}ⱼ are frame-specific and can be determined without reference to data from other frames. Frame-wise calibration can be efficient when large volumes of data (especially, of a high variability) have to be processed.

In summary, while temporal calibration focuses on continuous changes and can capture holistic or large-scale insights, frame-wise calibration zeroes in on specific moments, allowing for more localized analysis and versatility.

In some situations, implementing accurate calibration according to one of these two strategies can be challenging, as temporal calibration and frame-wise calibration represent two extremities of the calibration gamut. For example, temporal calibration may not offer a sufficient number of fitting parameters, also referred to degrees of freedom (DOF) herein, to properly capture changes of the model parameters {p} to characterize a sufficiently complex technological process.

On the other hand, frame-wise calibration may offer more DOFs thus allowing for more flexibility. This can be advantageous for capturing complex or highly variable processes. However, the increased complexity can introduce overfitting and unreliable process inference especially when the available data is not rich enough to uniquely resolve all DOFs of the models.

Aspects and embodiments of the present disclosure introduce efficient techniques for improved model calibration in the instances where using an intermediate number of DOFs may be more efficient than performing temporal calibration (with a low number of DOFs) or frame-wise calibration (with a high number of DOF). Systems and methods provided herein facilitate accurate and efficient processing of data using robust calibration strategies capable of enhanced versatility, adjustability with respect to DOFs, and in-situ applicability.

In some embodiments, a multi-model co-optimization calibration technique can be used. As in frame-wise calibration, a set of models Dⱼ (λ; {f}ⱼ) can be defined with a separate sets of floating parameters {f}ⱼ for different frames tⱼ. Knowledge of the physics and chemistry manufacturing processes can be used to identify a subset {c} of the floating parameters (e.g., a thickness of a film deposited on a wafer) that remain constant with time. These parameters—referred to as common floating parameters herein—can be allowed to float during calibration process with time but are forced to remain fixed (common) across the multiple models. The remaining (individual) parameters, denoted via {p}ⱼ, can float independently across both time frames and models. In some embodiments, each model Dⱼ(λ; {c}, {p}ⱼ) can undergo iterative optimization. For instance, during a given iteration, a particular model Dⱼ can be used to predict data values, e.g., a simulated reflectance, based on the current values of the common floating parameters {c} and individual floating parameters {p}ⱼ. A suitable loss function can then be used to evaluate an error/mismatch between the model-predicted data and the actual data collected for the respective times (frames). The loss function, e.g., a mean-squared error (MSE) loss function or some other loss function, can aggregate errors across multiple (e.g., some or all) models. An optimizer process can then update (e.g., incrementally) the models by changing the values of the common floating parameters {c}→{c′} and also changing individual floating parameters {p}ⱼ→{p′}ⱼ at each step of the iterative calibration. Like in frame-wise calibration, the parameters {p}ⱼ that vary with time are floating independently in each frame. The common floating parameters, which remain the same for multiple models, force and maintain cohesion across the models. The iterative optimization/calibration can be stopped at a point where the models achieve their maximum predictive power (given the number of DOF being used) and/or cease to improve further.

The following example illustrates differences between frame-wise calibration, multi-model calibration, and temporal calibration techniques. A manufacturing process (e.g., etching, deposition, polishing, etc.) can be modeled with five floating parameters p₁, . . . p₅, e.g., sample properties (including dimensions, chemical composition, and/or the like). The process can be characterized by ten collected sets of data (frames) t₁, . . . t₁₀. Correspondingly, in frame-wise calibration, 50 independent DOFs would be used to fit the collected data. In temporal calibration, each of the five floating parameters can be predicted (as an example) to have a linear dependence described by two independent constants (e.g., the initial value and rate of change) across all frames, for the total of 2× 5=10 DOFs. In multi-model calibration, where two of the floating parameters (e.g., p₁ and p₂) are expected to be common to all frames, the remaining three floating parameters can be varied independently for each of the ten frames, resulting in 2+3× 10=32 DOFs.

In some embodiments of the disclosure, a hybrid approach to multi-model calibration can be deployed. Within the hybrid approach, an initial model D(λ, t; {p}) may be obtained by applying temporal calibration (e.g., as disclosed above) to process data gathered in conjunctions with a manufacturing operation. Floating parameters {p} of the initial model can serve as initialization values for a set of frame-wise models D(λ, tⱼ; {p})→Seedⱼ (λ; {p}ⱼ), each seed model Seedⱼ (λ; {p}ⱼ) serving as the starting point for more accurate (static) calibration using the data of the specific frame tⱼ. Such individual-frame calibration causes the seed models to evolve to a multi-model set, Seedⱼ (λ; {p}ⱼ)→Dⱼ (λ; {p}ⱼ).

In some embodiments, temporal calibration can be deployed using a relaxed (e.g., spline-based) form. More specifically, instead of specifying (as part of a process model) a particular functional form for each floating parameter's dependence on time, e.g., p₁ (t), while leaving a fixed number of constants to be determined through fitting, relaxed temporal calibration can use spline-based fitting. For example, spline-based fitting can impose the condition that polynomial (in one illustrative example) splines are to connect a set of points (which can coincide, partially overlap, and/or be different from time frames) p₁(t₁), p₁(t₂), . . . p₁ (t_{N}) and can further impose the condition (in some instances) that the splines are to have a continuous first derivative p′₁ (t₁), p′₁ (t₂), . . . p′₁ (t_{N}) at those points.

In some embodiments, various disclosed calibration techniques can be used in conjunction with one or more regularization tools. Regularization refers to any regression mechanism that penalizes excessive variations of floating parameters {f} across different frame models, or otherwise drives individual frame models towards each other. In one example of regularization, a set of candidate values p(t₁), . . . p(t_{N}), of a certain floating parameter pⱼ (t) (index j being suppressed for conciseness) can be selected to fit a set of collected data. A regression line p_{reg} (t), e.g., a linear regression line, polynomial regression line, sigmoid regression line, etc., can be evaluated that represents a smoothed temporal change of the candidate values p(t₁), . . . p(t_{N}). For example, the regression line can minimize the combined error characterizing deviations of the candidate values from the regression line, e.g., err=Σₖ₌₁^{N}[p(tₖ)−p_{reg}(tₖ)]². The error can be included in a loss function as an additional term (to other terms that evaluate how close the candidate values fit the collected data) that weights the error by a certain “temperature” parameter θ, e.g., Loss=θ⁻¹·err. The temperature parameter θ can be selected empirically, based on how much large swings of the candidate values are tolerated. Lower temperatures θ more strongly penalize variations between the values of floating parameters across different models D₁ (λ; {p₁}), D₂ (λ; {p₂}), . . . Dₙ (λ; {pₙ}). Thus, at low temperatures, all frame-models may coalesce into one universal model and realize the limit of temporal calibration with a lower number of DOFs. At higher temperatures, more variations of the model parameters are tolerated, effectively allowing a higher number of DOFs with each frame model maintaining a level of uniqueness from other frame models.

The techniques of regularization can be used with any of the calibration techniques that lie on the continuum between the limits of frame-wise fitting and temporal calibration, e.g., (in the direction of degreasing the number of DOFs) multi-model optimization calibration and relaxed (spline-based) temporal fitting.

As described, temporal calibration, relaxed temporal calibration, multi-model calibration with co-optimization, hybrid multi-model with temporal seeding (with or without regularization), frame-wise calibration, and/or the like can be selected based on a desired target level of DOFs given a specific technological process. For instance, in cases where the collected spectral data is complex, and dependent on significant parameters, a more versatile calibration strategy (e.g., with more DOFs) can be deployed. In cases where a more unified model is preferred (e.g., as may be the case when the optical signal is less rich), a calibration strategy with fewer DOFs can be used.

In some embodiments, selection of one of the calibration options can be performed by a selection engine (e.g., a software/firmware module, code, algorithm, etc., executed by a processing device) that performs a preliminary analysis, e.g., statistical analysis, of the process data. For example, the ratio R of a standard deviation to a mean of the process data can be determined and compared with a set of thresholds R₁, R₂, etc., which represent (empirically determined) boundaries for deployment various calibration options. For example, temporal calibration can be used for R≤R₁, relaxed temporal calibration can be used for R₁<R≤R₂, multi-model calibration (co-optimization or hybrid) can be used for R₂<R≤R₃, frame-wise calibration can be used for R₃<R, and/or the like. Each calibration option can be performed by a respective calibration engine (which can be a separate software code or script) that is selected by the selection engine, e.g., as described above or using some other suitable selection technique.

In some embodiments, a combination of multiple calibration techniques can be used. For example, for certain floating parameter(s) that vary insignificantly and/or smoothly with time, temporal calibration can be used, while for other floating parameter(s) that show much greater variability with time, frame-wise fitting can be used. Yet for other floating parameter(s) having intermediate level of variability a multi-model optimization technique (with regularization, in some embodiments) can be used, and so on.

Accordingly, aspects of the present disclosure introduce enhanced modeling capabilities, through flexible selection of the number of DOFs (or effective degrees of freedom, through incorporation of regularization mechanisms into process modeling techniques). Such strategies can result in enhanced accuracy and versatility in in-situ OCD inference by augmenting the array of available models. Such adjustments offer a more granular and customizable approach to modeling. As a result, users are able to more effectively choose and fine-tune an appropriate model tailored to specific scenarios. Such customization not only enriches the depth and precision of modeling but also broadens the spectrum of scenarios that can be effectively represented.

In embodiments described herein, with respect to the current disclosure, “calibration” may at times be referred to as “fitting,” “training,” and/or “approximating a dataset.” In alternate embodiments used herein, “fitting,” “training,” and/or “dataset approximation,” may be or represent subsets, or variants, of “calibration.”

Calibration, as described herein, may include alternate language depending on the type(s) of model employed. E.g., a machine-learning model may be “trained,” while a statistical model may be “fitted.” Both strategies (as well as others) may be included in the term “calibrated.”

Similarly, in embodiments, multidimensional data or multidimensional sensor data may be referring to multivariate data or multivariate sensor data, within the disclosure to follow.

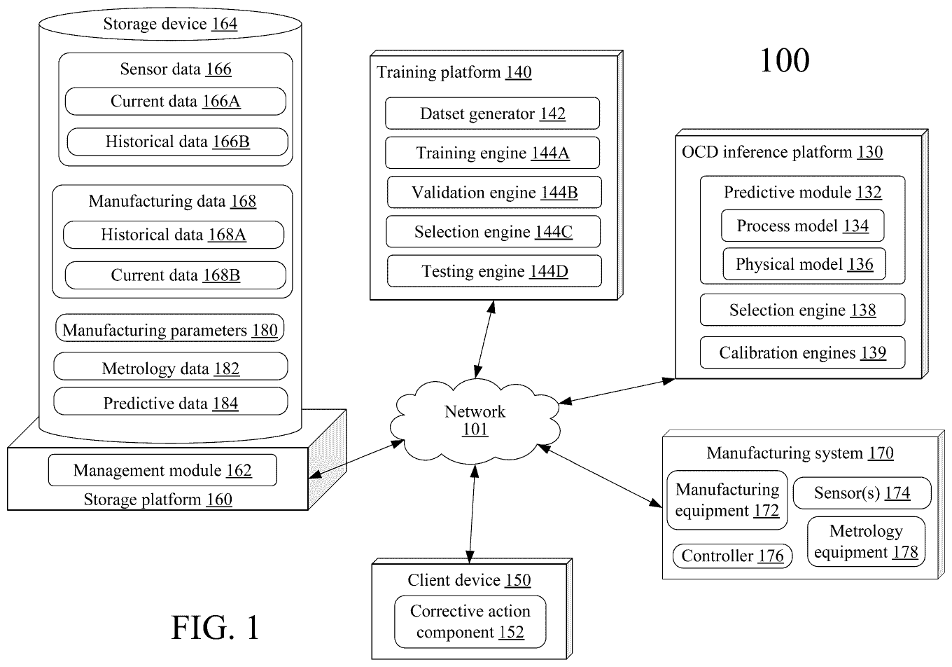

FIG. 1 illustrates an example system architecture capable of supporting a predictive module and a process model for generating optical critical dimension (OCD) inferences, according to some embodiments of the present disclosure.

The system 100 includes a client device 150, a manufacturing system 170, an OCD inference platform 130, a training platform 140, and a storage platform 160. Platforms 130, 140, and 160, manufacturing system 170, and client device 150 (including the associated components of each) may each connected to a network 101. In some embodiments, OCD inference platform 130, training platform 140, storage platform 160, and manufacturing system 170 can include, can be, or can otherwise be connected to one or more computing devices include one or more computing devices such as a rackmount server, a router computer, a server computer, a personal computer, a mainframe computer, a laptop computer, a tablet computer, a desktop computer, graphics processing unit (GPU), accelerator application-specific integrated circuit (ASIC) (e.g., tensor processing unit (TPU)), etc. OCD inference platform 130, training platform 140, storage platform 160, and/or manufacturing system 170 may include one or more virtual computing devices, e.g., cloud computing devices, cloud computing services, remote computing resources, etc.

In some embodiments, network 101 can include a public network (e.g., the Internet), a private network (e.g., a local area network (LAN) or wide area network (WAN)), a wired network (e.g., Ethernet network), a wireless network (e.g., an 802.11 network or a Wi-Fi network), a cellular network (e.g., a Long Term Evolution (LTE) network), routers, hubs, switches, server computers, and/or a combination thereof. In some embodiments, network 101 is a public network that provides client device 150 with access to OCD inference platform 130, storage platform 160, and/or other publicly available computing devices. In some embodiments, network 101 is a private network that provides client device 150 access to manufacturing system 170, manufacturing equipment 172, sensors 174, metrology equipment 178, storage device 164, and/or other privately available computing devices.

In some embodiments, manufacturing system 170 can include manufacturing equipment 172, sensors 174 associated with the manufacturing equipment, metrology equipment 178 (which may be included within sensors 174, in embodiments), and a controller, or control unit (e.g., controller 176).

In embodiments, manufacturing system 170 may include manufacturing equipment 172 e.g., which may be a cluster tool and/or part of a substrate processing system (e.g., integrated processing system). In some embodiments, manufacturing equipment 172 may include components of substrate processing systems. In some embodiments, manufacturing equipment 172 is used to produce one or more products (e.g., substrates, semiconductors, wafers, etc.). In some embodiments, manufacturing equipment 172 is used to produce one or more components to be used in substrate processing systems.

Manufacturing equipment 172 may be associated with one or more of a controller 176, an enclosure system (e.g., substrate carrier, front opening unified pod (FOUP), auto teach FOUP, process kit enclosure system, substrate enclosure system, cassette, etc.), a side storage pod (SSP), an aligner device (e.g., aligner chamber), a factory interface (e.g., equipment front end module (EFEM)), a load lock, a transfer chamber, one or more processing chambers, a robot arm (e.g., disposed in the transfer chamber, disposed in the front interface, etc.), and/or the like. The enclosure system, SSP, and load lock mount to the factory interface and a robot arm disposed in the factory interface is to transfer content (e.g., substrates, process kit rings, carriers, validation wafer, etc.) between the enclosure system, SSP, load lock, and factory interface. The aligner device is disposed in the factory interface to align the content. The load lock and the processing chambers mount to the transfer chamber and a robot arm disposed in the transfer chamber is to transfer content (e.g., substrates, process kit rings, carriers, validation wafers, etc.) between the load lock, the processing chambers, and the transfer chamber.

In embodiments, manufacturing equipment 172 may include one or more processing chambers used to produce or process substrates, such as semiconductor wafers. The properties of these substrates may be determined by conditions in which the substrates are processed. As substrate processing progresses, conditions in the chamber and/or the response of the substrate to those conditions may evolve. For example, a processing operation may include a substrate etching operation, e.g., an operation that removes material from the substrate. Processing parameters such as etch rate may change over the duration of the processing operation. Accurate understanding of temporal process parameter evolution may be used to predict properties of finished products, improve process learning, improve process recipe generation and refining, improve consistency of substrates produced, optimize substrate production, etc.

Sensors 174 (which may include metrology equipment 178, in embodiments) may provide sensor data 166 associated with manufacturing equipment 172 (e.g., associated with producing, by manufacturing equipment 172, corresponding products, such as wafers). Sensor data 166 may be used for equipment health and/or product health (e.g., product quality), for example. In embodiments, manufacturing equipment 172 may produce products following a recipe or performing processing operations and/or processing runs over a period of time. In embodiments, sensor data 166 may include values of one or more of temperature (e.g., heater temperature), spacing (SP), pressure, High Frequency Radio Frequency (HFRF), voltage of Electrostatic Chuck (ESC), electrical current, flow (e.g., of one or more gases), power, voltage, optical data (e.g., spectral data), acoustic data (e.g., substrate acoustic scattering data), etc. Sensor data may include in-situ measurements of a substrate in a processing chamber, e.g., a substrate undergoing processing operations.

In embodiments, any of sensors 174, including metrology equipment 178, may be placed within a processing chamber of the system 170. Thus, any processing chambers may include various sensors to report on conditions associated with processing the substrate, e.g., pressure and temperature sensors may report on chamber conditions, sensors may detect spontaneous plasma emission and report on conditions of the plasma, spectral or scatter of waves from the substrate may report on evolving substrate geometry, etc. Any of these or other sensors associated with a processing chamber may take multiple measurements in time over the duration of a processing operation.

In embodiments, the sensor data received from a processing chamber may be multidimensional (e.g., multivariate). Multidimensional (e.g., multivariate) data in this context indicates data resolved in more than one independent variable, wherein one of the independent variables is time. For example, spectral data associated with a processing operation may be resolved in wavelength and time, acoustic data may be resolved in frequency and time, pressure and temperature data may be resolved in sensor number and time, etc.

In embodiments, multidimensional sensor data may include data collected at asynchronous sampling rates and/or asynchronous sampling time points. For example, spectral data may be separated into a number of wavelength measurements (e.g., two dimensions of the multi-dimensional sensor data may be time and wavelength). In some systems, data associated with different wavelengths may be collected at different times, e.g., a spectrometer may collect data associated with a first wavelength at a first time, a second wavelength at a second time, etc. In some embodiments, the spectral data may repeat spectral measurements, e.g., spectral data associated with each wavelength may be collected multiple times, for example by cycling through the target wavelengths multiple times.

In embodiments, data from one or more sensors collected at the same time (or near the same time, e.g., analyzed as though the data was collected simultaneously) may be treated together to generate an indication of conditions at that time. For example, data from multiple pressure sensors may be analyzed to determine a snapshot of pressure conditions in a chamber, spectral data of a substrate may be processed to determine a snapshot of substrate surface geometry, etc.

Data collected from any of the sensing components (e.g., sensors 174, metrology equipment 178), may be kept within the manufacturing system for a time. In embodiments, such collected data may be transferred to storage platform 160, as will be further described below.

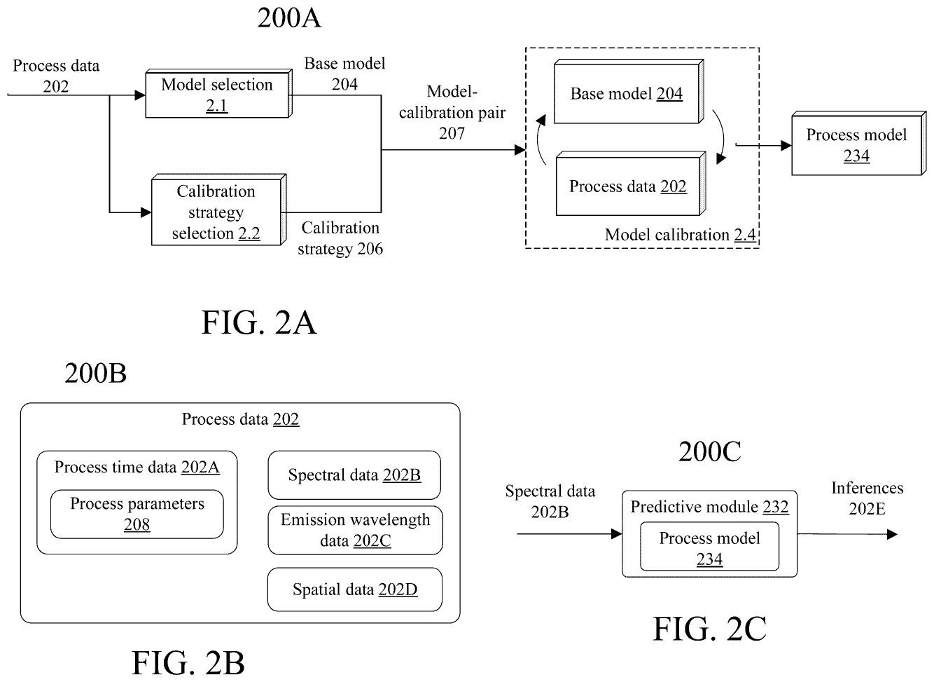

In embodiments, OCD inference platform 130 may perform, or direct to be performed, training, OCD inference design and execution, and house or host a predictive module 132 and process model 134 to accomplish such. In embodiments, OCD inference platform 130 may include a selection engine 138 (e.g., a software routine) that selects a model type, and calibration engines 139, that calibrate one or more models to fit one or more sets of process data. In embodiments, selection engine 138 can perform model selection and calibration strategy selection (as will be described in further detail with respect to FIG. 2A). In embodiments, calibration engines 139 can perform model calibration (as will be described in further detail with respect to FIG. 2A).

OCD inference platform 130 may include predictive module 132. Predictive module 132 may be used to generate predictive data 184. In some embodiments, predictive module 132 may receive sensor data 166, and/or manufacturing parameters 180 (e.g., receive from the client device 150, retrieve from the storage device 164) and generate output, e.g., predictive output, output for performing corrective actions associated with manufacturing equipment 172, etc., based on the provided data. In some embodiments, predictive module 132 may use one or more models 134 to determine the output for performing the corrective action based on current data.

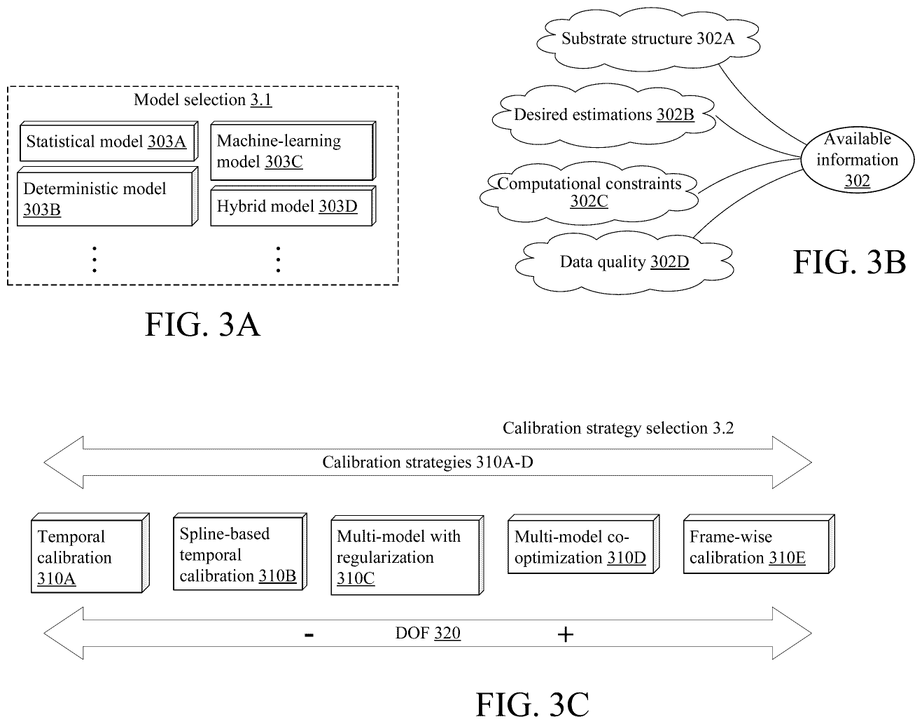

Model 134 may be a single model, an ensemble model, or a collection of models used to process data. Model 134 may include one or more physics-based, mathematical models, mathematical models, digital twin models, statistical models, stochastic models, deterministic models, supervised machine-learning models, unsupervised machine-learning models, semi-supervised machine-learning models, statistical models, etc., or any hybrid or combination of such or similar models as may be feasible. Further types and possibilities for model 134 will be described with respect to FIG. 3A.

In some embodiments, model 134 may store, record, update, and/or draw parameters reflective of substrate characteristics in a separate data unit model 136 (e.g., physical model 136). In embodiments, physical model 136 may house parameters or abstractions of optical or geometrical properties of a substrate (e.g., substrate characteristics).

In some embodiments, data indicative of properties of a substrate (e.g., current sensor data 166A) may be provided to a predictive module including one or more mathematical-based models. The predictive module may be configured to generate an indication of the temporal evolution of one or more processes (e.g., processing parameters), e.g., process time dependence, such as etch depth evolution, etch rate evolution, deposition rate evolution, etc. Current sensor data 166A provided to the predictive module (e.g., and/or model 134 of predictive module 132) and may be multivariate. E.g., in embodiments, the sensor data may be bivariate, including at least two independent variables, two independent axes, etc.

Bivariate sensor data may be resolved in time and at least one other dimension. For example, bivariate sensor data may include spectral data of a substrate in processing. The data may include data from several wavelengths (e.g., a first dimension of resolution may be wavelength) taken multiple times throughout a duration (e.g., a second dimensions of resolution of the data may be time). Possible dimensions of resolution may include wavelength (e.g., of electromagnetic radiation, including optical, IR, UV, X-Ray, etc., analysis), frequency (e.g., of acoustic signals), location (e.g., location of a sensor, location of spatially resolved data of a substrate, etc.), sensor ID, etc.

Model 134 may perform analysis operations (e.g., calibrating a mathematical model, generating output via a machine-learning model, etc.) upon the multidimensional data. In embodiments, multivariate sensor data (e.g., current sensor data 166A) may be provided to the modeling system after conclusion of a processing operation, e.g., sensor data indicative of the entire duration of an operation may be analyzed. In some embodiments, multivariate sensor data associated with a portion of the duration of a processing operation may be analyzed. In embodiments, multivariate sensor data may be analyzed holistically, e.g., data along multiple axes may be modeled simultaneously. In embodiments, multivariate sensor data may be analyzed as a series of frame-by-frame (e.g., time independent) analysis, stitched together (e.g., plotted on a time axis) to generate an indication of time evolution of a process. In embodiments, a hybrid, or combination, or other type or form of calibration may be performed, as will be further described within FIGS. 2-6.

In some embodiments, an approximation to a multi-variate mathematical model may be performed, e.g., a physical understanding of the evolution of multiple measurable parameters over time may be utilized to generate the physics-based mathematical model, generate a calibrated model, generate parameters for modeling process variable evolution, etc.

Predictive module 132 (e.g., via model 134) may generate multiple sets of features leveraging the model 134. For example a first set of features may correspond to a first set of types of sensor data (e.g., from a first set of sensors, first combination of values from first set of sensors, first patterns in the values from the first set of sensors) that correspond to each of the data sets (e.g., training set, validation set, and testing set) and a second set of features may correspond to a second set of types of sensor data (e.g., from a second set of sensors different from the first set of sensors, second combination of values different from the first combination, second patterns different from the first patterns) that correspond to each of the data sets. In some embodiments, training, validating, and/or testing sets may be utilizing in preparing a machine-learning model for operation.

Storage platform 160 may host and manage storage device 164. In some embodiments, a management module 162 may be used to manage communications, and storage device 164. In some embodiments, platform 160 may be a dedicated server for supporting storage device 164 accessible via network 101.

In embodiments, a management module, (e.g., management module 162) may reside at, or within, platform 160. The management module may oversee, regulate, and optimize operation associated with the storage device 164. The management module 162 may further accomplish tasks including, handling requests directed towards the storage device 164, ensuring the integrity and security of the data, managing backups, and orchestrating efficient use of storage resources provided by platform 160.

In some embodiments, when a data request or command is made to storage device 164, the request of command may first interface with the management module 162. The management module 162 may processes a request and determine the most efficient way to execute the request using the resources of the storage platform 160. Subsequently, the required data operations may be performed on storage device 164 and data 166, leveraging the underlying capabilities of the storage platform 160.

Storage device 164 may be a memory (e.g., random access memory), a drive (e.g., a hard drive, a flash drive), a database system, or another type of component or device capable of storing data. Storage device 164 may include multiple storage components (e.g., multiple drives or multiple databases) that may span multiple computing devices (e.g., multiple server computers). Storage device 164 may include remote storage, cloud data storage, cloud-based storage services, etc. Storage device 164 may store sensor data 166, manufacturing parameters 180, metrology data 182, and predictive data 184. Sensor data 166 may include sensor data time traces over the duration of manufacturing processes, associations of data with physical sensors, pre-processed data, such as averages and composite data, and data indicative of sensor performance over time (i.e., many manufacturing processes). Sensor data 166 may include multidimensional (e.g., multivariate) data, e.g., data resolved in both time and at least one other dimension.

Sensor data 166 may include current data 166A and historical data 166B. Current data, as used herein, indicates data associated with a processing run in progress or a processing run currently under analytic investigation, e.g., by providing sensor data, metrology data, manufacturing parameters, etc., to a machine-learning or physics-based, mathematical model. Manufacturing equipment 172 may be configured according to manufacturing parameters 180.

Manufacturing parameters 180 may be associated with or indicative of parameters such as hardware parameters (e.g., settings or components (e.g., size, type, etc.) of the manufacturing equipment 172) and/or process parameters of the manufacturing equipment. Manufacturing parameters 180 may include historical manufacturing data 168A and/or current manufacturing data 168B. Manufacturing parameters 180 may be indicative of input settings to the manufacturing device (e.g., heater power, gas flow, etc.). Sensor data 166 and/or manufacturing parameters 180 may be generated while the manufacturing equipment 172 is performing manufacturing processes (e.g., equipment readings when processing products). Sensor data 166 may be different for each product (e.g., each wafer).

In embodiments, metrology data 182 may corresponds to historical property data of products (e.g., produced using manufacturing parameters associated with historical sensor data and historical manufacturing parameters) and predictive data 184 is associated with predicted property data (e.g., of products to be produced or that have been produced in conditions recorded by current sensor data and/or current manufacturing parameters). In some embodiments, the predictive data 184 is predicted metrology data (e.g., virtual metrology data) of the products to be produced or that have been produced according to conditions recorded as current sensor data and/or current manufacturing parameters. In some embodiments, predictive data 184 is or includes an indication of abnormalities (e.g., abnormal products, abnormal components, abnormal manufacturing equipment, abnormal energy usage, etc.) and/or one or more causes of the abnormalities. In some embodiments, predictive data 184 includes an indication of change over time or drift in some component of manufacturing equipment 172, sensors 174, metrology equipment 178, and the like. In some embodiments, predictive data 184 includes an indication of an end of life of a component of manufacturing equipment 172, sensors 174, metrology equipment 178, or the like. In some embodiments, predictive data 184 includes a comparison of performance of a chamber, tool, recipe, product design, etc., to another.

In some embodiments, sensor data 166, metrology data 182, and/or manufacturing parameters 180 may be processed (e.g., by the client device 150 and/or by the OCD inference platform 130). Processing of sensor data 166 may include generating features. In some embodiments, the features are a pattern in the sensor data 166, metrology data 182, and/or manufacturing parameters 180 (e.g., slope, width, height, peak, etc.) or a combination of values from the sensor data 166, metrology data 182, and/or manufacturing parameters 180 (e.g., power derived from voltage and current, etc.). Sensor data 166 may include features and the features may be used by OCD module 132 for performing signal processing and/or for obtaining predictive data 184, possibly for performance of a corrective action. Predictive data 184 may be any data associated with OCD inference platform 130, e.g. predicted performance data of a substrate, of a substrate processing operation, of a component of manufacturing equipment 172, etc. In some embodiments, predictive data 184 may be indicative of substrate metrology. In some embodiments, predictive data 184 may be indicative of process conditions. In some embodiments, predictive data 184 may be indicative of temporal evolution of conditions, substrate characteristics, metrology, processing rate, etc., during the duration of a process operation.

Each instance (e.g., set) of sensor data 166 may correspond to a product (e.g., a wafer), a set of manufacturing equipment, a type of substrate produced by manufacturing equipment, a combination thereof, or the like. Each instance of metrology data 182 and manufacturing parameters 180 may likewise correspond to a product, a set of manufacturing equipment, a type of substrate produced by manufacturing equipment, a combination thereof, or the like. Storage device 164 may further store information associating sets of different data types, e.g. information indicative that a set of sensor data, a set of metrology data, and/or a set of manufacturing data are all associated with the same product, manufacturing equipment, type of substrate, etc. In some embodiments, predictive module 132 may generate predictive data 184 using machine-learning. In some embodiments, predictive module 132 may generate predictive data 184 with the use of one or more mathematical models.

Manufacturing parameters 180 and metrology data 182 may contain similar features, e.g., pre-processed data, associations between data and products/operations, etc. Sensor data 166, manufacturing parameters 180, and metrology data 182 may contain historical data (e.g., at least a portion for training various models represented in FIG. 1 by model 134). Metrology data 182 may be metrology data of produced substrates, as well as sensor data, manufacturing data, and model data corresponding to those products. Metrology data 182 may be leveraged to design processes for making further substrates. Predictive data 184 may include predictions of metrology data resulting from operation of a substrate support, predictions of component drift, aging, or failure, predictions of component lifetimes, predictions of processing parameter evolution over the duration of a processing operation, etc. Predictive data 184 may also include data indicative of components of system 100 aging and failing over time.

In embodiments, one or more client devices (e.g., client device 150) may be connected to the network. In embodiments, client device 150 may leverage and/or communicate with any other platforms of the system.

Client device 150 may include one or more computing devices such as personal computers (PCs), laptops, mobile phones, smart phones, tablet computers, netbook computers, network connected televisions (“smart TV”), network-connected media players (e.g., Blu-ray player), a set-top-box, over-the-top (OTT) streaming devices, operator boxes, etc. client device 150 may include one or more virtual computing devices, e.g., cloud-based computing devices, cloud computing services, etc. In embodiments, client device 150 may include a corrective action component 152.

Corrective action component 152 may receive user input (e.g., via a Graphical User Interface (GUI) displayed via the client device 150) of an indication associated with manufacturing equipment 172. The user interface may present an indication of evolution of a processing parameter, may present an indication of a corrective action to be performed, etc. In some embodiments, corrective action component 152 transmits the indication to the predictive module 132, receives output (e.g., predictive data 184) from predictive module 132, determines a corrective action based on the output, and causes the corrective action to be implemented.

In some embodiments, predictive module 132 may provide predictive data 184 to client device 150, and client device 150 causes a corrective action via corrective action component 152 in view of predictive data 184. In some embodiments, corrective action component 152 may receive current sensor data 166A associated with production of a substrate and provide the data to predictive module 132.

In some embodiments, the corrective action includes causing preventative operative maintenance (e.g., replace, process, clean, etc. components of the manufacturing equipment 172). In some embodiments, the corrective action includes causing design optimization (e.g., updating manufacturing parameters, manufacturing processes, manufacturing equipment 172, etc. for an optimized product). In some embodiments, the corrective action includes a updating a recipe (e.g., updating timing of manufacturing equipment 172 to be in an idle mode, a sleep mode, a warm-up mode, etc., updating set points such as temperature or pressure during a processing operation, etc.).

In embodiments, corrective action performed by component 152 may be associated with one or more of Computational Process Control (CPC), Statistical Process Control (SPC) (e.g., SPC on electronic components to determine process in control, SPC to predict useful lifespan of components, SPC to compare to a graph of 3-sigma, etc.), Advanced Process Control (APC), model-based process control, preventative operative maintenance, design optimization, updating of manufacturing parameters, updating manufacturing recipes, feedback control, machine-learning modification, or the like.

In some embodiments, the corrective action may include providing an alert (e.g., an alarm to stop or not perform the manufacturing process if predictive data 184 indicates a predicted abnormality, such as an abnormality of the product, a component, or manufacturing equipment 172) to a user. In some embodiments, performance of the corrective action includes causing updates to one or more manufacturing parameters. In some embodiments, performance of the corrective action includes causing updates to one or more calibration tables and/or equipment constants (e.g., a set point provided to a component may be adjusted by a value across a number of process recipes, for example voltage applied to a heater may be increased by 3% for all processes using the heater). In some embodiments, performance of the correction action includes updating a process recipe (e.g., to adjust an extent or rate of a processing parameter, such as etch rate, including horizontal etch rate, vertical etch rate, etc.; etch depth; deposition rate; deposition depth, etc.).

In some embodiments, corrective action component 152 stores data (e.g., data associated with intermediate analysis steps in generating predictive data 184) in storage device 164 and predictive module 132 retrieves the data from storage device 164. In some embodiments, predictive module 132 may store output (e.g., predictive data 184) of the trained model(s) 134 in storage device 164 and client device 150 may retrieve the output from storage device 164. In some embodiments, predictive module 132 may store output of the trained model(s) 134 in physical model 136 and client device 150 may retrieve the output from storage device 164. In some embodiments, corrective action component 152 receives an indication of a corrective action from predictive module 132 and causes the corrective action to be implemented. Each client device 150 may include an operating system that allows users to one or more of generate, view, or edit data (e.g., indication associated with manufacturing equipment 172, corrective actions associated with manufacturing equipment 172, etc.).

Performing manufacturing processes that result in defective products can be costly in time, energy, products, components, manufacturing equipment, the cost of identifying the defects and discarding the defective product, the cost of discovering and correcting the cause of the defect, etc. By inputting sensor data 166 (e.g., current sensor data 166A) into a predictive model (e.g., model 134), receiving output of predictive data 184, and performing a corrective action based on predictive data 184, system 100 can have the technical advantage of avoiding the cost of producing, identifying, and discarding defective products.

Performing manufacturing processes that result in failure of the components of the manufacturing equipment 172 can be costly in downtime, damage to products, damage to equipment, express ordering replacement components, etc. By inputting sensor data 166 (e.g., current sensor data 166A) to a predictive model (e.g., model 134), receiving output of predictive data 184, comparing data over time to diagnose drifting or failing components (e.g., also recorded as predictive data 184), and performing corrective actions (e.g., predicted operational maintenance, such as replacement, processing, cleaning, etc. of components, updating recipe parameters, etc.) based on the predictive data 184, system 100 can have the technical advantage of avoiding the cost of one or more of unexpected component failure, unscheduled downtime, productivity loss, unexpected equipment failure, product scrap, or the like. Monitoring the performance over time of components, e.g. manufacturing equipment 172, sensors 174, metrology equipment 178, and the like, may provide indications of degrading components. Monitoring the performance of a component over time may extend the component's operational lifetime, for instance if, after a standard replacement interval passes, measurements indicative that the component may still perform well (e.g., performance above a threshold) for a time (e.g., until the next planned maintenance event).

Manufacturing parameters may be suboptimal for producing products which may have costly results of increased resource (e.g., energy, coolant, gases, etc.) consumption, increased amount of time to produce the products, increased component failure, increased amounts of defective products, etc. By inputting the sensor data 166 into a calibrated or trained model (e.g., model 134), receiving an output of predictive data 184, and performing (e.g., based on predictive data 184) a corrective action of updating manufacturing parameters (e.g., setting optimal manufacturing parameters), system 100 can have the technical advantage of using optimal manufacturing parameters (e.g., hardware parameters, process parameters, optimal design) to avoid costly results of suboptimal manufacturing parameters.

In some embodiments, predictive module 132 may access and leverage the functionalities of calibration platform 140.

Training platform 140 may include a data set generator 142 that is capable of generating data sets (e.g., a set of data inputs and a set of target outputs) to train, validate, and/or test model 134. Some operations of data set generator 142 are described in detail below. In some embodiments, data set generator 142 may partition historical data (e.g., historical sensor data, historical metrology data, etc.) into a training set (e.g., sixty percent of the data), a validating set (e.g., twenty percent of the data), and a testing set (e.g., twenty percent of the data).

Training platform 140 may further include a training engine 144A, a validation engine 144B, selection engine 144C, and/or a testing engine 144D. An engine (e.g., training engine 144A, a validation engine 144B, selection engine 144C, and a testing engine 144D) may refer to hardware (e.g., circuitry, dedicated logic, programmable logic, microcode, processing device, etc.), software (such as instructions run on a processing device, a general-purpose computer system, or a dedicated machine), firmware, microcode, or a combination thereof. The training engine 144A may be capable of training a model 134 using one or more sets of features associated with the training set from data set generator 142. The training engine 144A may generate multiple trained models 134, where each trained model 134 corresponds to a distinct set of features of the training set (e.g., sensor data from a distinct set of sensors). For example, a first trained machine-learning model may have been trained using all features (e.g., X1-X5), a second trained machine-learning model may have been trained using a first subset of the features (e.g., X1, X2, X4), and a third trained machine-learning model may have been trained using a second subset of the features (e.g., X1, X3, X4, and X5) that may partially overlap the first subset of features. Data set generator 142 may receive the output of a trained model (e.g., 134), collect that data into training, validation, and testing data sets, and use the data sets to train a second model. Some or all of the operations of training platform 140 may be used to train various types of models, including physics-based, mathematical models, supervised machine-learning models, unsupervised machine-learning models, etc.

Validation engine 144B may be capable of validating a trained model 134 using a corresponding set of features of the validation set from data set generator 142. For example, a first trained model 134 that was trained using a first set of features of the training set may be validated using the first set of features of the validation set. The validation engine 144B may determine an accuracy of each of the trained models 134 based on the corresponding sets of features of the validation set. The validation engine 144B may discard trained models 134 that have an accuracy that does not meet a threshold accuracy. In some embodiments, the selection engine 144C may be capable of selecting one or more trained models 134 that have an accuracy that meets a threshold accuracy. In some embodiments, the selection engine 144C may be capable of selecting the trained model 134 that has the highest accuracy of the trained models 134.

Testing engine 144D may be capable of testing a trained model 134 using a corresponding set of features of a testing set from data set generator 142. For example, a first trained model 134 that was trained using a first set of features of the training set may be tested using the first set of features of the testing set. The testing engine 144D may determine a trained model 134 that has the highest accuracy of all of the trained models based on the testing sets.

Model 134 may refer to a model (e.g., a machine-learning model, a statistical mathematical model, etc.) describing temporal evolution of sensor data over a duration associated with a processing operation. The model may be configured to solve equations describing the flow energy, spectral of light, interaction with acoustic stimuli, etc., in and around a substrate. The model may be refined by training, e.g., measuring properties of a substrate over a processing operation and utilizing results to refine model (e.g., by calibration one or more parameters to the experimental data).

As previously mentioned, in some embodiments, model 134 may store, record, update, and/or draw parameters reflective of substrate characteristics in a separate data unit model 136 (e.g., physical model 136). In embodiments, physical model 136 may house parameters or abstractions of optical or geometrical properties of a substrate (e.g., substrate characteristics).

In embodiments model 134 may refer to a machine-learning model, which may be the model artifact that is created by the training engine 144A using a training set that includes data inputs and corresponding target outputs (correct answers for respective training inputs). Patterns in the data sets can be found that map the data input to the target output (the correct answer), and the machine-learning model 134 is provided mappings that captures these patterns. In some embodiments, machine-learning model 134 may predict properties of substrates. In some embodiments, machine-learning model 134 may predict failure modes of manufacturing chamber components. In some embodiments, machine-learning model 134 may predict evolution of processing parameters over a duration associated with a processing operation.

Predictive module 132 may be capable of determining predictive data 184, including predictions (e.g., inferences) on finished substrate properties and predictions (e.g., inferences) of effective lifetimes of components of manufacturing equipment 172, sensors 174, or metrology equipment 178 based on the output of model 134. Predictive module 132 or corrective action component 152 may use the confidence data to decide whether to cause a corrective action associated with the manufacturing equipment 172 based on predictive data 184. In some embodiments, training, validating, and/or training sets may be utilizing in preparing a model for operation, e.g., to account for incorrect assumptions in model building, to account for unknown parameters (e.g., differences in manufacturing equipment components within manufacturing tolerances), etc. In some embodiments, data indicative of properties of a substrate produced (e.g., current sensor data 166A) is provided to a trained machine-learning model (e.g., model 190). The machine-learning model is trained to output data indicative of a corrective action to produce a substrate with different characteristics. In some embodiments, data indicative of evolution of a processing parameter (e.g., etch depth, etch rate, etc.) is output by the machine-learning model. In some embodiments, data indicative of a corrective action to adjust evolution of a processing parameter is output by the machine-learning model (e.g., a recipe adjustment).

Historical sensor data may be used in combination with current sensor data to detect drift, changes, aging, etc. of components of manufacturing equipment 172. Sensor data 166 monitored over time may generate information indicative of changes to a processing system, e.g., component drift or failure, sensor drift or failure, maintenance to be performed, recovery of a chamber after maintenance is performed, etc. Predictive module 132 may use combinations and comparisons of sensor data 166, manufacture parameters 180, metrology data 182, etc. to generate predictive data 184. In some embodiments, predictive data 184 includes data predicting the lifetime of components of manufacturing equipment 172, sensors 174, etc.

In some embodiments, sensor data from a number of chambers may be used to detect chamber operational differences, perform chamber matching procedures, etc. Sensor data 166 generated by multiple chambers may be provided to modeling system, e.g., model 134. Model 134 may be used to generate an indication of temporal processing parameter evolution over the duration of a processing operation in multiple processing chambers. Differences is processing parameter evolution between chambers may indicate chamber matching procedures to be performed, e.g., recipe update, maintenance, component replacement, etc.

In some embodiments, predictive module 132 may receive data, such as sensor data 166, metrology data 182, manufacturing parameters 180, etc., and may perform pre-processing such as extracting patterns in the data or combining data to new composite data. Predictive module 132 may then provide the data to model 134 as input.

Model 134 may include one or more physics-based, mathematical models, digital twin models, machine-learning models, etc., and may accept as input sensor data. Model 134 may include a trained machine-learning model, a statistical model, etc., configured to further process data associated with properties of a substrate support. Predictive module 132 may receive from model 134 predictive data, indicative of chamber performance, predicted substrate properties, a manufacturing fault, component drift, or the like. Predictive module 132 may then cause a corrective action to occur. The corrective action may include sending an alert to client device 150. The corrective action may also include updating manufacturing parameters of manufacturing equipment 172. The corrective action may also include generating predictive data 184, indicative of chamber or instrument drift, aging, or failure, recipe success or failure, predicted product properties, etc.

In embodiments, predictive module 132 may be capable of determining (e.g., extracting) predictive data 184 from the output of the trained machine-learning model 134 and may determine (e.g., extract) confidence data from the output that indicates a level of confidence that the predictive data 184 is an accurate predictor of a process associated with the input data for products produced or to be produced, or an accurate predictor of components of manufacturing equipment 172.

Confidence data may include or indicate a level of confidence. As an example, predictive data 184 may indicate the properties of a finished substrate given a set of manufacturing inputs, including the use of a substrate support described with substrate support data. The confidence data may indicate that the predictive data 184 is an accurate prediction for products associated with at least a portion of the input data. In one example, the level of confidence is a real number between 0 and 1 inclusive, where 0 indicates no confidence that the predictive data 184 is an accurate prediction for products processed according to input data and 1 indicates absolute confidence that the predictive data 184 accurately predicts properties of products processed according to input data. Responsive to the confidence data indicating a level of confidence below a threshold level for a predetermined number of instances (e.g., percentage of instances, frequency of instances, total number of instances, etc.) the predictive module 132 may cause the trained machine-learning model 134 to be re-trained (e.g., based on current sensor data 166A, current manufacturing parameters 180, etc.).

For purpose of illustration, rather than limitation, aspects of the disclosure describe the training of one or more models 134 using historical data and inputting current data into the one or more trained models 134 to determine predictive data 184. In other implementations, a heuristic model or rule-based model is used to determine predictive data (e.g., without using a trained machine-learning model). Predictive module 132 may monitor historical data and metrology data 182. Any of the information described with respect to data inputs may be monitored or otherwise used in the heuristic or rule-based model.

In some embodiments, any of the modules and or platforms can host or leverage an AI model (e.g. a local AI model) for decision making associated with the respective module.

In one embodiment, such an AI model (including process model 134, in embodiments) may be one or more of decision trees, random forests, support vector machines, or other types of machine-learning models. In one embodiment, such an AI model may be one or more artificial neural networks (also referred to simply as a neural network). The artificial neural network may be, for example, a convolutional neural network (CNN) or a deep neural network.

In embodiments, processing logic performs supervised machine-learning to train the neural network.

In embodiments, the artificial neural network(s) may generally include a feature representation component with a classifier or regression layers that map features to a target output space. A convolutional neural network (CNN), for example, may host multiple layers of convolutional filters. Pooling may be performed, and non-linearities may be addressed, at lower layers, on top of which a multi-layer perceptron is commonly appended, mapping top layer features extracted by the convolutional layers to decisions (e.g., classification outputs). The neural network may be a deep network with multiple hidden layers or a shallow network with zero or a few (e.g., 1-2) hidden layers. Deep learning is a class of machine-learning algorithms that use a cascade of multiple layers of nonlinear processing units for feature extraction and transformation. Each successive layer uses the output from the previous layer as input. Neural networks may learn in a supervised (e.g., classification) and/or unsupervised (e.g., pattern analysis) manner. Some neural networks (e.g., such as deep neural networks) include a hierarchy of layers, where the different layers learn different levels of representations that correspond to different levels of abstraction. In deep learning, each level learns to transform its input data into a slightly more abstract and composite representation.

In embodiments, such an AI model may be one or more recurrent neural networks (RNNs). An RNN is a type of neural network that includes a memory to enable the neural network to capture temporal dependencies. An RNN is able to learn input-output mappings that depend on both a current input and past inputs. The RNN will address past and future measurements and make predictions based on this continuous measurement information. One type of RNN that may be used is a long short-term memory (LSTM) neural network.

As indicated above, such an AI model may include one or more generative AI models, allowing for the generation of new and original content, such a generative AI model may include aspects of a transformer architecture, or a GAN architecture. Such a generative AI model can use other machine-learning models including an encoder-decoder architecture including one or more self-attention mechanisms, and one or more feed-forward mechanisms. In some embodiments, the generative AI model can include an encoder that can encode input textual data into a vector space representation; and a decoder that can reconstruct the data from the vector space, generating outputs with increased novelty and uniqueness. The self-attention mechanism can compute the importance of phrases or words within a text data with respect to all of the text data. A generative AI model can also utilize the previously discussed deep learning techniques, including recurrent neural networks (RNNs), convolutional neural networks (CNNs), or transformer networks. Further details regarding generative AI models are provided herein.

In embodiments, such an AI model can be an AI model that has been trained on a corpus of textual data. In some embodiments, the AI model can be a model that is first pre-trained on a corpus of text to create a foundational model, and afterwards fine-tuned on more data pertaining to a particular set of tasks to create a more task-specific, or targeted, model. The foundational model can first be pre-trained using a corpus of text that can include text context in the public domain, licensed content, and/or proprietary content. Such a pre-training can be used by the model to learn broad language elements including general sentence structure, common phrases, vocabulary, natural language structure, and any other elements commonly associated with natural language in a large corpus of text.

In embodiments, the AI model can then be further trained and/or fine-tuned on organizational data, including proprietary organizational data. The AI model can also be further trained and/or fine-tuned on process data associated with a manufacturing operation or a processing chamber operation or a manufacturing system at large.

In some embodiments, such an AI model may include one or more pre-trained models, or fine-tuned models. In a non-limiting example, in some embodiments, the goal of the “fine-tuning” may be accomplished with a second, or third, or any number of additional models. For example, the outputs of the pre-trained model may be input into a second AI model that has been trained in a similar manner as the “fine-tuned” portion of training above. In such a way, two more AI models may accomplish work similar to one model that has been pre-trained, and then fine-tuned.

In some embodiments, storage device 164 may be hosted by one or more storage devices, such as main memory, magnetic or optical storage-based disks, tapes or hard drives, network-attached storage (NAS), storage area network (SAN), and so forth. In some embodiments, storage device 164 may be a network-attached file server, while in other embodiments, storage device 164 may be or host some other type of persistent storage such as an object-oriented database, a relational database, and so forth.

In some embodiments, storage device(s) 164 may be hosted by any of the platforms or device associated with system 100 (e.g. OCD inference platform 130). In other embodiments, storage device 164 may be on or hosted by one or more different machines (e.g., OCD inference platform 130 and training platform 140) coupled to the system via network 101. In some implementations, the storage device 164 may store portions of audio, video, text, or process data received from the client device (e.g. client device 150) and/or any platform and any of its associated modules of the system.

In some embodiments, any one of the associated platforms (e.g. training platform 140) may temporarily accumulate and store data until it is transferred to storage devices 164 for permanent storage.

It is appreciated that in some implementations, the functions of platforms 130, 140 and/or 160 may be provided by a fewer number of machines. For example, in some implementations, functionalities of platforms 130, 140 and/or 160 may be integrated into a single machine, while in other implementations, functionalities of platforms 130, 140 and/or 160 may be integrated into multiple, or more, machines. In addition, in some implementations, only some platforms of the system may be integrated into a combined platform.

While the modules of each platform are described separately, it should be understood that the functionalities can be divided differently or integrated in various ways within the platform while still applying similar functionality for the system. Furthermore, each platform and associated modules can be implemented in various forms, such as standalone applications, web-based platforms, integrated systems within larger software suites, or dedicated hardware devices, just to name a few possible forms.

In general, functions described in embodiments as being performed by platforms 130, 140 and/or 160 may also be performed by client devices (e.g. client device 150). In addition, the functionality attributed to a particular component may be performed by different or multiple components operating together. Platforms 130, 140 and/or 160 may also be accessed as a service provided to other systems or devices through appropriate application programming interfaces, and thus is not limited to use in websites.

It is appreciated that in some implementations, platforms 130, 140 and/or 160 or client devices of the system (e.g. client device 150) and/or storage device 164, may each include an associated API, or mechanism for communicating with APIs. In such a way, any of the components of system 100 may support instructions and/or communication mechanisms that may be used to communicate data requests and formats of data to and from any other component of system 100, in addition to communicating with APIs external to the system (e.g., not shown in FIG. 1).

In embodiments, a “user” may be represented as a single individual. However, other embodiments of the disclosure encompass a “user” being an entity controlled by a plurality of users and/or an automated source. For example, a set of individual users federated as a group of administrators may be considered a “user.”

Embodiments of the disclosure may be applied to data quality evaluation, feature enhancement, model evaluation, Virtual Metrology (VM), Predictive Maintenance (PdM), limit optimization, or the like.

Although embodiments of the disclosure are discussed in terms of generating predictive data 184 to perform a corrective action in manufacturing facilities (e.g., semiconductor manufacturing facilities), embodiments may also be generally applied to improved data processing by utilizing multidimensional sensor data (e.g., process data) to perform a holistic data fit, and use the fitted data to improve processing conditions, parameters, set points, processes, etc.

FIG. 2A illustrates an example process for generating the process model of FIG. 1, according to some embodiments of the present disclosure.

In embodiments, the process 200A of FIG. 2A may include and describe similar components as were described with respect to FIG. 1. For instance process 200A may describe a training process as applied by training module 144A of FIG. 1. Process 200A may include a process model 234 and process data 202 that may correspond to, be similar to, or include components of process model 134 and sensor data 166. These components, as described with respect to FIG. 2A, may incorporate and augment at least the embodiments of similar components seen and described with respect to FIG. 1.

In embodiments, the system 100 of FIG. 1 may employ process 200A to calibrated and produce a process model 134. In embodiments, process 200A may be effected by training engine 144A, and other modules of training platform 140.

In embodiments, the process model may be a mathematical model (e.g., such as an electromagnetic solver) and may provide a correlation between received sensor data and a physical system (e.g., substrate). As was previously described in respect to FIG. 1, in embodiments, the process model 234 may be a time-dependent model, e.g., may describe the evolution of properties of the physical system (e.g., substrate characteristics) over time. For example, the process OCD model 234 may describe the evolution of spectral data as etch depth increases over the duration of a processing operation. In some embodiments, there may be no evolution, or the model parameter describing a substrate characteristic may be constant. As previously mentioned, in some embodiments, process model 234 may store, record, update, and/or draw parameters reflective of substrate characteristics in a separate data unit model (e.g., a physical model). In embodiments, such a physical model may house parameters or abstractions of optical or geometrical properties of a substrate (e.g., substrate characteristics).

In embodiments, the process 200A may begin with selecting a model and a calibration strategy. In embodiments, model selection 2.1 and calibration strategy selection 2.2 may be accomplished sequentially, with model selection 2.1 preceding calibration strategy selection 2.2. In some embodiments, this sequence may be reversed.

In alternate embodiments, due to the intimacy between a model type and an applied calibration strategy, operations 2.1 and 2.2 may be accomplished in tandem. As will be further described with respect to FIG. 3A-C, multiple versions of models and calibration strategies may be selected. Both model selection and calibration strategy selection may be influenced by the type of process data available, the parameters needed to be inferred, the associated manufacturing process, as well as the calibration strategy that will be used.

Model types employed by the process 200A may vary, according to process parameters and computational requirements, etc. For instance, in embodiments, the model may be a statistical model such as a polynomial model, a linear model, a spline model, a logarithmic model, etc. In alternate embodiments deterministic models, or specialty models including elements such as Fourier series, wavelet functions, gaussian mixtures, hidden Markov model, or an electromagnetic solver may be used. In alternate embodiments, a machine-learning model such as a decision tree, a random forest, a neural network, or other support vector machine (SVM). In alternate embodiments, a combination, ensemble, or hybrid mode model including any of the above-mentioned models may be used. These types of models, and others, were discussed with respect to FIG. 1, and will be further described with respect to FIG. 3A-C.

Calibration strategies employed by process 200A may also vary, according to process parameters and computational requirements, etc. Various types of calibration strategies will be further described with respect to FIGS. 3A-C. A selected base model 204 and calibration strategy 206 may be referred to as a model-calibration pair 207.

Once a model and a calibration strategy have been selected, the process may execute the calibration strategy according to a model calibration operation 2.4. Such an operation may vary, depending on the mode-calibration pair. For example, if the model selected is a machine-learning model, during operation 2.4, an optimization regime may be used to iteratively adjust the parameter of the based model 204, until the model has been adequality calibrated to process data 202. If a more straightforward statistical, or deterministic model, is selected, the calibration process may not be iterative. Thus, model calibration 2.4 may depend heavily on the model type, and will be further discussed with respect to FIGS. 3A-C. In embodiments, such a calibrated model may store, record, update, and/or draw parameters reflective of substrate characteristics in a separate data unit (e.g., a physical model) housing parameters or abstractions of optical or geometrical properties of a substrate (e.g., substrate characteristics).

Through such a model calibration process, the base model 204 (and included parameters) may approach a calibrated model and parameters, or process model 234.

Once calibrated (i.e., trained, or fitted), the process model 234 may be used to generate a variety of inferences. In some embodiments, the process model 234 may accept time-resolved data associated with spectrally resolved detection of electromagnetic radiation. In embodiments, the model 234 may include parameters (e.g., within terms of the model), representing the evolution of a process behavior, substrate behavior, or substrate characteristic (e.g., etch depth, etch rate, deposition rate, etc.). In some cases, the model parameters may represent the behavior itself (e.g., represent a physical characteristic, as opposed to its change). In embodiments, a model parameter may be expressed as a function of time and/or a number of other parameters and variables (e.g., polynomial coefficients, other independent variables, etc.) that are derived by the process model 234 based on the multi-dimensional process data. In other embodiments, the model parameters may be constant. In some embodiments, representations of the substrate characteristics may be stored, recorded, updated, and/or drawn from a separate data unit (e.g., a physical model). In embodiments, such a physical model may house parameters or abstractions of optical or geometrical properties of a substrate (e.g., substrate characteristics).

Further description of a modeling system for analysis of multi-variate, multidimensional sensor data will be found with respect to FIG. 2C and FIGS. 3A-C.

FIG. 2B illustrates an example data structure of the process data of FIG. 2A, according to some embodiments of the present disclosure.

In embodiments, components of FIG. 2B such as processing data 202, may correspond, or be similar, to processing data 202, as seen and described in FIG. 2A, or similar data structures as seen and described with respect to FIG. 1, and incorporate and augment at least the embodiments described therein.

Processing data 202 may be multidimensional and/or multivariate data. In some embodiments, processing data 202 may include process time data 202A, spectral data 202A, emission wavelength data 220C, and spatial data 202D. In embodiments, process time data 202A may include, or influence, other parameters, and variables (e.g., secondary, or “derived,” parameters and variables). These may be parameters contingent on any combination of the independent variables. For example, in embodiments, a processing chamber pressure, temperature, etc. may be contingent on process time data. In embodiments, substrate characteristics, such as etch rate, changes in critical dimensions, etc., may be dependent, and modeled as a function of process time data 202A. Thus, process parameters 208 may include process or substrate characteristics that are dependent on time data 202A.

In embodiments, time data 202A may include a dataset, or range of time corresponding to the beginning of a process, e.g., plasma etching, deposition, etc. During such a process, spectral data 202B may be captured by sensors associated with the process. Thus, in embodiments, the data may be linked, or “resolved” with respect to the independent variables (e.g., process time data 202A). In embodiments, emission wavelength data 202C may be data representative of emitted spectral electromagnetic light, during the process. Spatial data 202D may be data indicating the spatial location of the portion of the substrate that is being exposed to, and is reflecting, the emitted spectral light.

In embodiments, process time data 202A and emission wavelength data 202C may correspond to independent variables of processing data 202. In embodiments, process time data 202A may be time measurements corresponding to the duration of a process, while all data was collected. As was described with respect to FIG. 1, in embodiments, emission wavelength data 202C may correspond to emitted wavelength data during the process. As was described with respect to FIG. 1, in embodiments, spectral data 202B may be sensed data from system sensors, and may be dependent on time data 202A and emission wavelength data 202C.

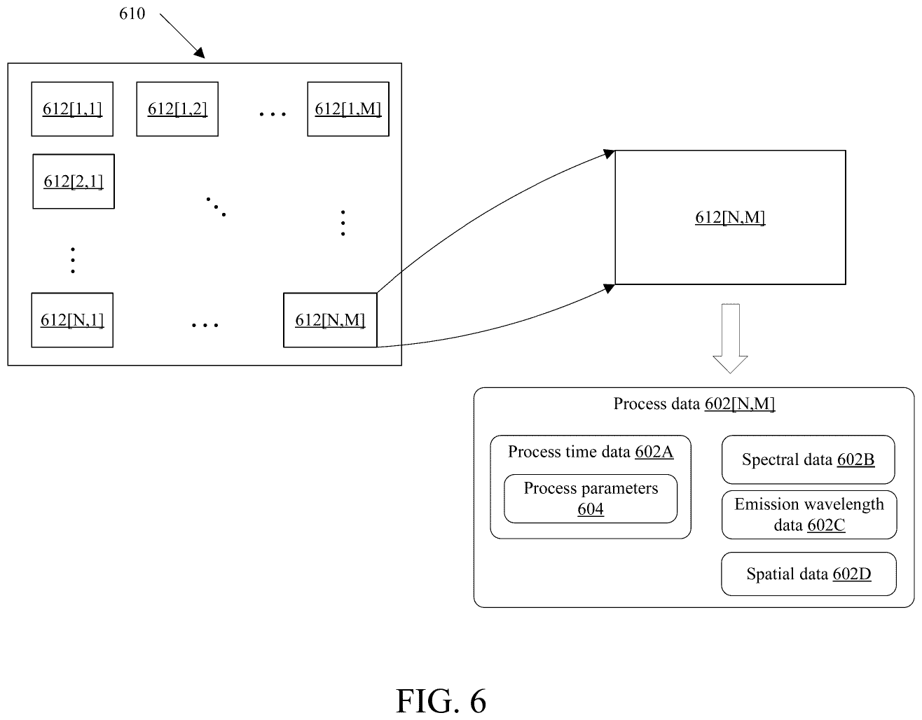

In embodiments, spatial data 202D may not be included in the data set, or data structure. In alternate embodiments where it is included, spatial data 202D may function as an independent variable of process data 202. Spatial data 202D may indicate the spatial location of an area, or segment of substrate that is providing the spectral data 202B. Spatial data will be further discussed with respect to FIG. 6 below.

FIG. 2C illustrates an example process for generating substrate characteristic inferences with the process model of FIG. 2A, according to some embodiments of the present disclosure.

In embodiments, the process 200C of FIG. 2C may include and describe similar components as were described with respect to FIGS. 1 and 2A-B. For instance, process 200C may describe a prediction process as applied by predictive module 132 and model 134 and/or 234 of FIGS. 1 and 2A-B. Process 200C may include a predictive module 232, process model 234, spectral data 202B, and inferences 202E that may correspond to, be similar to, or include components of predictive module 132, process model 134 and/or 234, sensor data 166, predictive data 184, and spectral data 202B, as seen and described with respect to FIGS. 1 and 2A-B, and incorporate and augment at least the embodiments described therein.

In embodiments, once a process model 234 has been calibrated to the data, the spectral data 202B may be input to the predictive model 232 (and/or process model 234), and inferences 202E may be extracted. In embodiments, the inferences 202E may correspond to critical dimensions (or temporal evolutions thereof) of the substrates, as has been previously described with respect to FIG. 1.

In some embodiments, such inferences 202E may have been stored within a separate physical model which includes parameters reflective of substrate characteristics, and the inferences 202E for substrate characteristics may simply be extracted from the physical model.

In embodiments, the process 200C may be applied in-situ, as has been previously described. For instance, as a manufacturing operation is occurring, spectral data may be gathered and provided to predictive module 232, which may generated inferences 202E in real-time.

FIG. 3A illustrates an example model selection subprocess of FIG. 2A, according to some embodiments of the present disclosure.

As seen in FIG. 3A, in embodiments, model selection 3.1 may correspond, or be similar to model selection 2.1, as seen and described in FIG. 2A. Accordingly, model selection 3.1 may incorporate and augment at least the embodiments described with respect to model selection 2.1 in FIG. 2A.

As seen within FIG. 3A, and as previously discussed, multiple mathematical models may be used to approximate the process data. Furthermore, the selection of a model type may be influenced by a variety of factors.

In embodiments, the model selection process may include a mathematical model for modeling the process data. Such a mathematical model may provide a correlation between sensor data and a physical system (e.g., substrate). The mathematical model may be a time-dependent model, e.g., may describe the evolution of properties of the physical system (e.g., substrate) over time. In embodiments, mathematical model may be a time-dependent model and emissions wavelength dependent model. In some embodiments, such a mathematical model may be coupled with a physical model, for storing, recording, updating, and/or drawing parameters reflective of substrate characteristics. In embodiments, such a model may operate as a function of any combination of the variables 202A, 202C, or 202C, as seen and described with respect to FIG. 2B.

In some embodiments, for example, such a model may be a statistical model 303A, as is known in the art. Statistical models may be linear models, polynomial models, spline models, or any similar, or combination of such or similar, mathematical model.

In embodiments, the physics-based, mathematical model may be a multivariate model, e.g., such as a bivariate model, trivariate model, etc.

In some embodiments, the statistical model may be a composite model, or a comprehensive model including many unique individual models (e.g., frame models, as employed in frame-wise calibration).

In some embodiments, a mathematical model such as a bivariate polynomial model may accept time-resolved data associated with spectrally-resolved detection of electromagnetic radiation. In embodiments, the mathematical model may include model terms representing a process behavior (e.g., etch depth, etch rate, deposition rate, etc.) and/or a substrate characteristic (e.g., a critical dimension). Process behaviors and/or characteristics may be expressed as a function of time and/or a number of term parameters (e.g., polynomial coefficients) that are derived by calibrating the bivariate polynomial model (or whichever model is selected) based on the multi-dimensional sensor data (e.g., the process data).

In an example of such a statistical model that might be selected in subprocess 3.1, a modifiable, mathematical model such as a univariate, bivariate, or trivariate polynomial function may provide adequate versatility for use as a physics-based mathematical model. In a non-limiting example of a simplified mathematical model, in embodiments, such a bivariate polynomial model may take the form of P(x, y)=Σᵢ₌₀^{N}Σⱼ₌₀^{M} aᵢⱼtⁱe^{j}. In such a polynomial, t may represent process time, e may represent an emitted wavelength, and N and M may represent the order of the polynomial, and may be as high or low as necessary to adequately capture process parameters indicative of substrate characteristics. As seen, “a” may represent one or more polynomial coefficients, to be solved for, as was discussed with respect to FIG. 1. In some embodiments, such coefficients may be stored, recorded, updated, and/or drawn from the parameters of a physical model reflective of substrate characteristics. For example, a single term of the polynomial (e.g., aᵢⱼtⁱe^{j}) may represent the effect of a substrate characteristic on emissions data, as a function of time. Such a term might describe the evolution of spectral data as etch depth increases over the duration of a processing operation. Thus, the model P(x,y) may produce simulated spectral data, based on a given time and emitted wavelength, or a series of such variables.

While the above example is useful as an instrument that demonstrates certain concepts within the present disclosure, it is important to bear in mind that the above-provided example is illustrative, nonlimiting, and a highly-simplified embodiment of a statistical model, or mathematical model, that may be used within any of the above-described, or following models and methods.

In alternate embodiments, pre-established or deterministic mathematical model (e.g., deterministic model 303B) may be employed. Deterministic model 303B may be any suitable deterministic model, such as the thin-film model, a rigorous coupled-wave analysis (RCWA) model, a finite-different time-domain (FDTD) model, a transfer matrix method (TMM), etc., (or a hybrid of such or similar models) and can be used to arrive at a calibrated process model.

In embodiments, these model types (and others) can rely on a variety of underlying mathematical structures and functions to provide complex modeling capabilities.

In embodiments, a thin-film model may employ additive Fresnel equations to describe how light interacts with each layer of the substrate. Such a cumulation of Fresnel equations may be simple and/or linear. E.g., in embodiments, the Fresnel equation employed may be a set of linear equations that can be solved efficiently. Such equations may be based on the boundary conditions of Maxwell's equations and provide a way to calculate reflection and transmission coefficients for each layer. To achieve such simplicity, such a model may make vast assumptions to simplify the real-world substrate, and process. E.g., such a model may assume that each layer is homogeneous and isotropic, characterized by a single refractive index, a single absorption coefficient, etc.

In a similar vein of mathematical model, in embodiments, an effective medium approximation (EMA) may be employed. An EMA-based model may include homogenization techniques to represent the substrate as a single, effective medium. Similar to a Fresnel equation-based model or a TMM model, the effective refractive index and absorption coefficients may be utilized. Weighted averages of the constituent materials may be taken to model a substrate as a monolithic medium. Thus, the underlying mathematical structure may be relatively simple, e.g., involving algebraic equations that relate the effective properties to the properties of the individual materials.

In slightly more complex embodiments, a TMM-based model may employ a matrix formulation to describe how light propagates through each layer. Such a model may incorporate elements of the EMA model. For example, for each layer, a 2×2 matrix (or other dimensional matrix) may be constructed based on the boundary conditions and material properties. The matrices for all layers may then multiplied together to find the overall transfer matrix, which is used to calculate the reflection and transmission coefficients. Such a mathematical structure may be linear and involve matrix manipulations (e.g., multiplication, inversion, etc.), making a TMM-based model computationally efficient in comparison to some of the above models. In embodiments, such a model may be non-linear.

In more sophisticated embodiments, an RCWA-based model may be employed. The RCWA-based model may involve more complex mathematical structures. E.g., such a model may involve solving Maxwell's equations in the frequency domain for periodic structures. Such a model—may involve producing one or more scattering matrices, to simulate spectral based on substrate parameters. The one or more scattering matrices may then be calibrated to the process data. Thus, in embodiments, such a model may employ one or more complex equations and structures to represent the fields and materials. In embodiments, such equations may have to be numerically solved, prior to calibration.

Similar in complexity, an FDTD-based model may solve Maxwell's equations in the time domain using finite-difference approximations. In embodiments, computational domain is discretized into a grid, and the electromagnetic fields are updated at each grid point as a function of time. Solving the partial differential equations included within Maxwell's equations numerically (in a similar fashion as may be required with the RCWA-based model) may cost considerable computational time. However, once resolved, the model may offer high accuracy for more complex structures.

In some embodiments, the model may include or be a machine-learning model 303C. Such a model was described with respect to FIG. 1, and the embodiments discussed therein are incorporated and augmented herein, with respect to FIG. 3A and model 303C. In embodiments, the machine-learning model may be configured to accept as input sensor data and generate as output an indication of evolution of processing parameters. In some embodiments, a machine-learning model may be configured to perform a subset of operations involved in the modeling system.

In embodiments, machine-learning models may provide additional versatility and capacity when compared to the above-described mathematical models. This may come at the cost of added training time and lower computational efficiency.

In embodiments, hybrid models 303D may involve combining the mathematical structures of multiple models. For example, a machine-learning model might be coupled with Fresnel equations and a thin film model to handle both simple and complex features. Combinations such as this may be utilized to optimize computational load and time. In embodiments, any of the above-mentioned models (which may also include physical models of the substrate characteristics), and/or combinations of such may be employed. The mathematical structure in such cases can thus be a combination or result of linear and nonlinear equations, eigenvalue problems, iterative methods, etc.

One of ordinary skill in the art, having the benefit of this disclosure, will appreciate that numerous models, model-types, mathematical functions, combinations, and configurations for a base model of the model selection process exist, and that the above list is non-exhaustive. One of ordinary skill in the art, having the benefit of this disclosure, will appreciate that the above-recited models as seen and described are exemplary representations of possible models to be employed by the process of FIG. 2A, and the system at large.

As discussed above, a large variety of models, ranging in complexity, computational requirements, parameter inclusion, and underlying mathematical functions may be used.

As such, selecting a model, as is done in operation 3.2, may be influenced by a variety of factors. Such a section may rely on prior manufacturing process experience and/or data, substrate knowledge such as structural and experimental data of a substrate within a process, knowledge of the model and its mathematical capabilities, functions, etc. Some of these influencing factors may be seen in FIG. 3B as factors 302A-D.

FIG. 3B illustrates example information influencing the model selection subprocess of FIGS. 2A and 3A, according to some embodiments of the present disclosure.

As seen in FIG. 3B, in embodiments, selection of a model may rest on available information 302. In embodiments, one of these factors may be the complexity (or lack thereof), and other details of a substrate's geometry or physical structure (e.g., substrate structure 302A). For example, a simple, layered substrate structures may be adequately modeled using a thin-film model and/or linear mathematical equations. In alternate embodiments, substrates may include more intricate features, such as gratings or complex multi-layer arrangements. Such substrates may be better modeled, or only be capable of being modeled, by models such as the RCWA-based model, for example. Thus, the physical properties of a substrate involved with a manufacturing process may influence the selection of a model.

In embodiments, the desire for specific substrate characteristic inferences (e.g., desired inferences 302B) may also of interest also play a significant role in model selection. For instance, if the primary concern is to measure layer thickness, or a specific, single parameter, a simpler model may suffice as opposed to a more comprehensive model. In embodiments, where several, or more complex features e.g., sidewall angles or non-uniform material properties, etc. are desired, a more sophisticated model may be required to capture such nuances.

Computational resources or constraints 302C may also be another important consideration when selecting a model. For example, the thin-film model may be computationally efficient and straightforward to implement. Other more complex models may demand higher computational, or hardware, capabilities, including processing time. For example models like FDTD and RCWA may require specialized hardware for efficient execution. If computational resources are limited, a simpler, less resource-intensive model may be employed, possibly at the expense of some level of accuracy. In cases where processing time can have an impact (e.g., such as when the model will be used in-situ), such constraints may guide model selection 3.1 and/or 2.1.

In embodiments, the quality and quantity of the data collected (e.g., data quality 302D) can also influence the choice of model. In embodiments, sparse or noisy data may necessitate the use of a model that can incorporate statistical or probabilistic elements. Simpler, or lower-order models may perform better with noisy, or sparce data when compared to more complex models.

Thus, in embodiments, multiple factors, including but not limited to factors 302A-D as seen in FIG. 3B, may influence the model selection process 3.1. One of ordinary skill in the art, having the benefit of this disclosure, will appreciate that numerous additional factors or considerations for selecting a model-type exist, and that factors 302A-D as seen in FIG. 3B are an exemplary representation of influencers. One of ordinary skill in the art, having the benefit of this disclosure, will appreciate that numerous additional influencing factors may influence model selection process 3.1 and/or 2.1.

FIG. 3C illustrates an example calibration strategy selection subprocess of FIG. 2A, according to some embodiments of the present disclosure.

As mentioned previously, in embodiments, model selection 3.1 may be intimately related with calibration strategy selection 3.2, and factors 302A-D may equally influence calibration strategy selection. In embodiments, calibration strategy selection may precede model selection, or vise-versa. In embodiments, the two operations may be accomplished in tandem.

Calibration strategy selection 3.2 may correspond, or be similar to calibration strategy selection 2.2, as seen and described in FIG. 2A, in embodiments. Accordingly, calibration strategy selection 3.2 may incorporate and augment at least the embodiments described with respect to calibration strategy selection 2.2 in FIG. 2A.

As seen within FIG. 3B, multiple calibration strategies may be used to calibrate a model to the process data. As was mentioned, in embodiments, “calibration” may at times be referred to as “fitting,” “training,” and/or “approximating a dataset.” In embodiments used herein, “fitting,” “training,” “approximation,” and/or “optimization,” may be or represent subsets, or variants, of “calibration.”

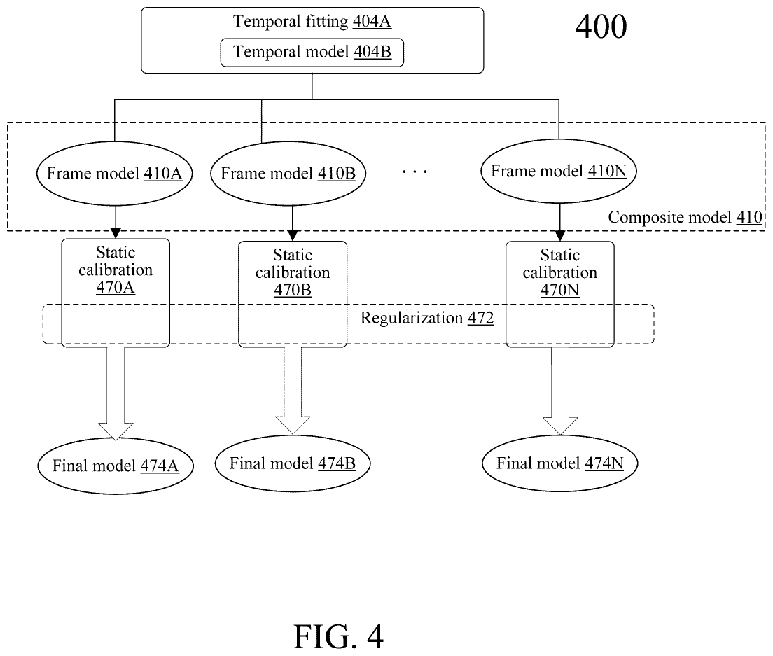

In embodiments, any of calibration strategies 310A-E (or others), implemented by the respective engine, may be applied to calibrate a model to the process data, as was described with respect to FIG. 2A. For example, a temporal calibration strategy 310A, a spline-based temporal calibration strategy 310B, a multi-model calibration strategy with regularization 310C, a multi-model strategy with co-optimization 310D, a frame-wise calibration strategy 310E, etc., may be used by the process of FIG. 2A. One of ordinary skill in the art, having the benefit of this disclosure, will appreciate that numerous additional calibration strategies, including subsets and variations of those presented in FIG. 3C, exist. One of ordinary skill in the art, having the benefit of this disclosure, will appreciate that the provided calibration strategies as seen in FIG. 3C are non-exhaustive. A non-limiting discussion of such strategies will now be provided, and further variations will be described with respect to FIGS. 4-6.

In embodiments, a temporal calibration 310A strategy, may be used. In embodiments, temporal calibration may approximate multivariate process holistically. As mentioned previously, approximating multivariate data holistically may provide advantages to other methods. For example, in embodiments where spectral data may be sparse, e.g., spectral data may be resolved into a fairly small number of wavelength measurements (for example, to reduce measurement time so as to not delay processing operations).

Approximating sparse data may limit the amount of information extractable from the analysis, e.g., due to overfitting. Sparse data may also be more sensitive to noise than data sets including a larger number of data points. In embodiments, holistic calibration strategies for the multivariate data may alleviate these or similar challenges by utilizing data points collected at multiple times in a calibration/fitting scheme. More data points included in the process data may increase the volume of extractable information (e.g., the number of dimensions of a product that may be predicted, the accuracy to which the temporal evolution of a processing parameter or substrate characteristic may be predicted, etc.). In such a way, reliability of information extraction, increases resistance of analysis to noisy signals, etc., may be increased.

In embodiments, a variation of temporal calibration 310A, such as spatial temporal calibration, or spline-based temporal calibration 310B, etc., may be used.

In embodiments, a relaxed temporal calibration, e.g., spline-based temporal calibration 310B strategy may be used. In an example of such an embodiment, the model selected may be a spline-based model (which may be piecewise-defined polynomial functions), to approximate the relationships within measure process data. In embodiments of a spline-based, temporal calibration strategy, the substrate's features or properties may be represented using spline functions. Such spline functions may include sets of boundary points. These boundary points may serve as floating parameters in the calibration process and may be optimized to achieve the best fit between the measured and simulated data using a cost, or loss function. Such a cost, or loss function will be further described below with respect to optimization.

In embodiments, the use of splines may allow for higher degree of flexibility (e.g., degrees of freedom (DOF)) in capturing intricate variations in the data, when compared to strict temporal calibration. Thus, spline-based temporal calibration 310B may be useful for substrates with non-uniform properties or complex geometries. A further discussion of DOFs and their relation within calibration strategies will be provided further below.

In embodiments, a version of temporal calibration, e.g., a spatial temporal calibration strategy may be employed within process 200A of FIG. 2A. A spatial temporal calibration strategy may incorporate multiple sets of process data taken across multiple sections of a substrate being processed. For example, the model selected within model selection 3.1 may typically be a bivariate model, including time, and emitted wavelengths as independent variables. Such models may correlate continuous reflected, or spectral values, as a function of time and emitted wavelengths.

However, employing a spatial temporal calibration strategy may require a trivariate model. Such a model may include time, emitted wavelength, and spatial locations as independent variables. Such a model may correlate quantify the relationship between three independent variables, and at least one dependent variable. In embodiments, the dependent variable may contain spectral values, which may be modeled as a function, of time, emitted wavelength, and spatial location.

A spatial-temporal calibration strategy may employ algorithms that consider the spatial correlations between different regions, allowing for the extraction of parameters that may vary across the substrate. This type of calibration strategy and model may be particularly useful for substrates with non-uniform properties or localized defects, as it provides a more comprehensive understanding of the spatial variations. Such a model will be described in further detail with respect to FIG. 6.

In a generalized embodiment of temporal, spline-based temporal and/or spatial temporal calibration, batch calibration may be used. Batch calibration may involve the simultaneous calibration of multiple data sets, which could be from different manufacturing batches (e.g., spatial batches, as in spatial temporal calibration), different points in time (temporal batches), or any set of process data that has been segmented. This approach enhances the statistical reliability of the extracted parameters by pooling data, thereby providing more robust inference capabilities at the expense of versatility and DOFs.

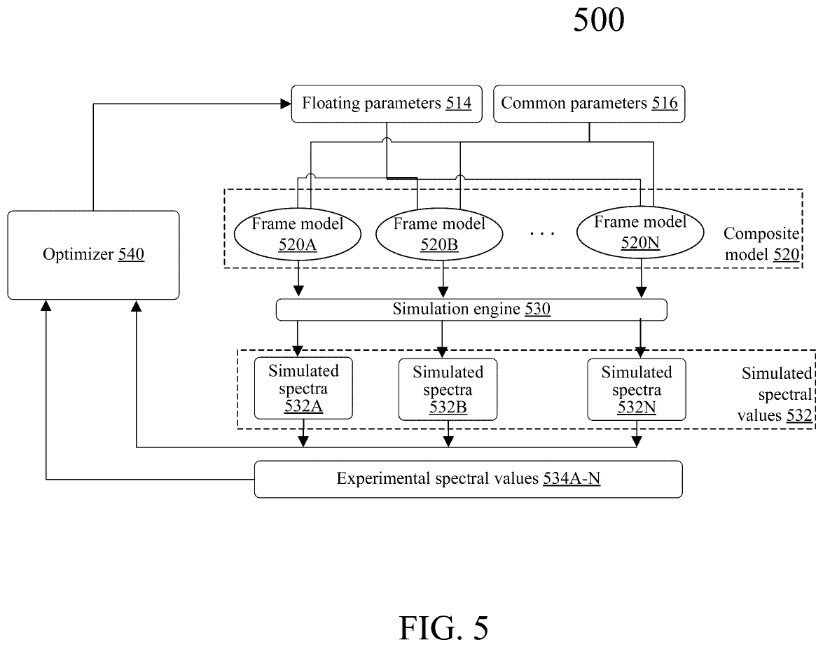

In embodiments, multi-model calibration (e.g., multi-model with regularization 310C and/or multi-model co-optimization 310D, hybrid multi-model, etc.) may be applied. Such may be a variation of “sequential calibration,” (where one calibration strategy precedes another) and may employ a two-step (or more than two-step) approach where initial inferences of some parameters are first obtained using a simpler model or calibration method. These initial inferences serve as starting points for a more complex or comprehensive calibration strategy. This strategy can significantly improve the efficiency and convergence time of the calibrating (e.g., fitting or training) process. In embodiments, a multi-model calibration strategy can include regularization (e.g., multi-model with regularization 310C), such a strategy will be further discussed with respect to FIGS. 4-5.

In embodiments, multi-model calibration strategies (at times “ensemble calibration strategies” herein) may employ a collection of models and/or calibration strategies to generate an ensemble of possible solutions. Each member of the multi-model ensemble represents a different set of extracted parameters, and the ensemble as a whole can be analyzed to provide statistical measures.

In embodiments, an ensemble or multi-model strategy may be particularly useful for estimating a diverse set of parameters during a manufacturing process. For example, if it is known that certain parameters are unchanging, or easily modeled, they may be inferred with a linear model and a temporal calibration strategy (or similar strategy). In the same processing and calibration process, more complex parameters and calibration strategies may be used for more complex parameters. This multi-model approach is especially valuable when there is significant uncertainty in either the model or the measurements, as it provides a more robust estimate of the parameters.

In embodiments, multi-model calibration strategies (e.g., multi-model with regularization 310B and/or multi-model co-optimization 310D) may combine any of the above, or below, described strategies. In embodiments, for example, a separate calibration strategy may be used for each parameter. In embodiments, any combination as is feasible may be used. In some embodiments, multiple models may be co-optimized (as will be further described with respect to FIG. 5).

In embodiments, a frame-wise calibration strategy 310E may be used. Frame-wise calibration may model multivariate spectral data segment-wise, or “frame-by-frame.” For example, in embodiments including the time domain, frame-wise calibration may iteratively model distinct time instances of the data, with a distinct model, often referred to as a frame model, or sub-model. Aggregately, the combined models may be referred to as the “composite model.” Frame-wise calibration may provide additional or the highest amount of degrees of freedom, but is prone to some hurdles (e.g., overfitting, as was previously discussed). Frame-wise calibration may at times be referred to as “static calibration,” herein.

As mentioned, selecting a calibration strategy may include a variety of influencing factors. Such factors may be similar, or equivalent to the factors seen with respect to operation 3.1. For example, in embodiments, complexity of the substrate structure 302A may matter. For instances, for substrates with non-uniform properties or localized defects, spatial temporal calibration may be the most appropriate strategy to capture these variations. On the other hand, for substrates that are relatively uniform but produced in different batches or at different times, batch calibration may be more suitable to understand process variability.

In embodiments, the specific substrate or process characteristics to be inferred (e.g., desired inferences 302B) may also play a significant role. For example, in embodiments, if the focus is on a single, highly specific parameter, a targeted approach like sequential calibration, as opposed to temporal calibration, may be more suitable.

Computational resources (e.g., computational constraints 302C), are another important factor. For example, strategies like ensemble or hybrid calibration may involve running multiple models or simulations, and can be computationally intensive and may require specialized hardware. In embodiments where computational resources are limited, simpler, “light” strategies like temporal calibration, or variations of temporal calibration may be applied.

Similarly to operation 3.1, data quality 302D and quantity also influence the choice of calibration strategy. For example, with sparse or noisy data, hybrid or temporal calibration strategies can provide a more robust estimate by generating a range of possible solutions. In cases where data is abundant and high-quality, more complex methods like batch calibration, or multi-model calibration may be more accessible and preferred.

One of ordinary skill in the art, having the benefit of this disclosure, will appreciate that numerous methods, combinations, and applications for calibration strategies exist, and that the above-described strategies are exemplary, and non-exhaustive. As such, one of ordinary skill in the art, having the benefit of this disclosure, will appreciate that numerous further methods and combinations of such may exist to accomplish similar calibrations for a process model.

As discussed, each model and calibration strategy may provide varying levels, of adaptability, comprehensiveness, and sensitivity to data (and even further models and calibration strategies will be discussed below). A useful concept when comparing such models and calibration strategies may be the degrees of freedom (DOF or DOFs, as previously mentioned). DOFs may capture the adaptiveness offered by each combination and calibration process.

Degrees of freedom, in embodiments, may refer to, and depend on, the number of tunable, or adjustable parameters within an overall model. In embodiments, parameters may be defined as common, which are unaffected by, of agnostic to, changes in independent variables (e.g., parameters that apply to every time-frame of the process data), or floating parameters, which fluctuate and change along with independent variables. E.g., in frame-wise calibration, a floating parameter may apply specifically to one frame of the process data. In embodiments, floating parameters may afford a model additional DOFs, as they may be changed and altered between frames of the data.

In embodiments, for example, floating parameters may be variables that are allowed to change freely during the optimization process to achieve the best approximation between the measured data and the computational model. These parameters may be unconstrained by prior information or other variables and are optimized to minimize the difference between the model's predictions and the actual measurements. For example, in spatial temporal calibration, the refractive index in different spatial regions could be treated as a floating parameter, if it is expected to vary across the substrate. Similarly, in frame-wise calibration, every or almost all parameters maybe floating parameters across data frames. These variables may all be unique, and optimized simultaneously to satisfy different criteria, such as minimizing residuals within a specific frame (e.g., within frame-wise calibration).

Common parameters, on the other hand, may be variables that are kept constant across different sets of data or different regions of the substrate during the calibration process. Such parameters are assumed to be uniform and are not optimized individually for each data set or region. Within batch calibration, for example, the layer thickness might be treated as a common parameter if it is assumed to be consistent across different manufacturing batches. In sequential, or multi-model calibration, a common parameter could be a fundamental material property such as the bulk refractive index, which is assumed to be the same at all scales or levels of the model.

Thus, in embodiments where a modeling goal is to capture the variability in a substrate with non-uniform properties, floating parameters may be assigned. Alternatively, in embodiments where a substrate is expected to have uniform properties, or if the focus is on understanding commonalities across different batches or time points, common parameters may be more suitable.

In embodiments, a hybrid approach may be employed, where some parameters are treated as floating while others are kept common. For example, in ensemble or hybrid calibration, different ensemble members might share some common parameters while having individual floating parameters to account for uncertainties in the model or measurements.

As might be expected, common and floating parameters choices are intimately tied to the choice of calibration strategy. For example, if a temporal or temporal-spatial calibration strategy is selected, all parameters may be “forced” to be common. Alternatively, should a frame-wise calibration strategy be selected all parameters may have the potential to be floating. In such a way, the concept of degrees of freedom of a model and calibration strategy may be introduced.

Each specific model and calibration strategy may vary in DOFs. At one end of the spectrum may be temporal calibration 310A strategies, which may have the least DOFs, while at the other end, frame-wise calibration may have the most versatility. Other strategies may lay somewhere in between. In a highly-simplified example, in embodiments, let us assume a temporal calibration strategy and appropriate model are selected to adjust 10 model parameters. Since the calibration strategy will be temporal, all parameters will be common across all frames and segments of the data. Otherwise stated, only 10 parameters may be tuned to model the process data. Thus, such a model-calibration pair may have restricted DOFs. In embodiments, the model-calibration pair may have 10 DOFs, corresponding to 10 tunable parameters. In a separate but similar example, for instance a frame-wise calibration and appropriate model is used for calibrating (i.e., adjusting) 10 parameters. There may be 10 frames within the data i.e., that the data is divided into 10 frames. In such a calibration process, all parameters, across the entire model will be floating, and each frame of the 10 frames will have 10 unique parameters after calibration. Thus, 100 different total parameters may be tuned, and the model-calibration pair may have 100 DOFs, compared to the previous 10. Thus, in such a way, DOFs may vary according to calibration strategy, parameters, and models. This variation in DOFs may be intentionally exploited, and optimized, to generate a model-calibration pair that best suits a process, desired parameters, and constraints.

DOFs of a model and calibration strategy may serve as a quantifier to characterize the adaptability or variability, in the overall model (e.g., the composite model in frame-wise calibration). For example, since frame-wise calibration may include a substantial amount of frame specific frame models that may each include their respective parameters, such a model may have a high DOFs. This may be enhanced if the specific frame model within is complex, with many parameters and variables. In embodiments where each parameter of each frame model of the composite model is floating, very high DOFs are possible. In contrast, in embodiments, where one model is applied to all data (e.g., such as was mentioned with respect to temporal or spatial-temporal calibration), the DOFs, or variability and versatility in the model may be quite limited.

Higher DOFs may be beneficial for a model, at the cost of added computation, more stringent data quality requirements, and the risk of overfitting the model. Lower DOFs may be used when such a versatile or nimble calibration strategy and model are not required.

As discussed above, since calibration strategies and models may be mixed, matched and combined, even within one calibration process, the DOFs of a process may be engineered, or designed, to provide a model adequate for the process data at hand, and the parameters which are desired. Such methods of designing will be further discussed with respect to FIGS. 4-6, below.

After a model-calibration pair has been selected (as described with respect to FIGS. 2A-3B), in embodiments, an optimization regime (at times herein referred to as an “inference method,” or “optimizer”) for the calibration process may also need to be selected.

Optimization regimes, or optimizers, may be used by the calibration process 200A of FIG. 2A, and embodiments seen in FIGS. 2B-3C can be varied, and, again, depend on the model and calibration strategy selected.

In embodiments where a simpler model (e.g., a thin-film, or linear based model) has been selected, for example, a one or more optimizers (e.g., inference methods) such as least-squares methods (LSM), maximum likelihood inference (MLE), etc. may be used.

In embodiments, an LSM optimizer may be suitable. This strategy minimizes the sum of the squares of the differences between the measured and simulated data. For example, in embodiments employing a thin-film model, the LSM method may be computationally efficient and provide a straightforward way to extract parameters such as layer thickness and refractive index.

In other embodiments, different, or combinations of optimizers (e.g., such as MLE) may be more appropriate and/or beneficial. E.g., MLE may consider the probability distribution of the data, making it robust to outliers and noise. This may be useful when the mathematical model is nonlinear and/or a fitting landscape has multiple local minima.

In more complex models, including use of machine-learning models, specialized optimization regimes, such as gradient descent or simulated annealing, etc. may be employed to find the global minimum of the likelihood function.

Bayesian methods, Markov Chain Monte Carlo (MCMC) techniques, etc. may be employed as well, and may provide inferences of the parameters but also uncertainty intervals.

In cases where a large, comprehensive, high-dimensional machine-learning model has been used, further optimization strategies such as stochastic gradient descent (SGD), ADAM, or RMSprop, etc., may be employed.

Furthermore, in embodiments, during optimization, regularization techniques may also be applied in attempts to minimize overfitting, but also to curtail the DOFs of a model-calibration pair. Such regularization will be described in further detail with respect to FIG. 4. Common types of regularization that can be used include least absolute shrinkage and selection operator (LASSO) (L1 regularization), ridge regression (RR) (L2 regularization), or other types of feasible regularization. Such regularization can also be applied across various types of mathematical models. In general, these techniques add a penalty term to the optimization function or regime, constraining the range of possible solutions. This is useful for preventing overfitting when the number of parameters is large, or when available data is comparatively small.

One of ordinary skill in the art, having the benefit of this disclosure, will appreciate that numerous varieties and combinations of calibration, fitting, training, optimization, and/or regularization strategies exist for any types of the above-mentioned models, and the above-discussed methods (including regularization methods) are meant to be non-exhaustive. One of ordinary skill in the art, having the benefit of this disclosure, will appreciate that numerous further methods and combinations of such exist, and may be applied to achieve similar effects and calibrated models as discussed above.

FIG. 4 illustrates an example multi-model calibration with regularization strategy of FIG. 3C, according to some embodiments of the present disclosure.

In embodiments, a hybrid calibration with regularization strategy 400 can include aspects of both static (i.e., frame-wise calibration), and elements of temporal calibration. Thus, in embodiments, the hybrid calibration strategy of FIG. 4 may at times be referred to as hybrid calibration with regularization (as will be further described below).

In embodiments, calibration strategy 400 may begin with a temporal calibration 404A of a process data with a temporal model 404B. In embodiments, temporal model 404B and calibration 404A may include or be any feasible calibration strategy or model as was described with respect to FIG. 3A-C.

After temporal calibration 404A has been accomplished, and model parameters have been inferred, floating and common parameters may be determined. As was described with respect to FIG. 3C, in some embodiments, temporal calibration 404A may highlight, or show, which parameters produced by the model and temporal calibration strategy 404A are constant for a process, and which are mutable, or “changing.”

After floating parameters have been established, a form of static calibration with regularization may be applied. To begin, static calibration 470A-N may be applied for each frame model 410A-N, as has been previously described with respect to FIG. 3C.

In embodiments, the static calibration may include a regularization mechanism 472, that may penalize variances in the floating parameters, as each individual model is calibrated. Thus, as the models are calibrated according to static (e.g., frame-wise) calibration strategies, each final frame model 410A-N may begin to approximate every other frame model of 410A-N, through convergence in the floating parameter values. Thus, in embodiments, final models 474A-N may bear resemblance to one another but maintain uniqueness. Should a level of regularization be sufficient (e.g., as controlled via a temperature parameter), models 474A-N may become identical. Thus, in embodiments, regularization 472 may generate one final model (e.g., final models 474A-N may be identical) for the process data.

In embodiments, the temperature parameter may thus provide a tunable parameter adjusting DOFs of the model-calibration pair. For example, in embodiments, the regularization term may takes the form of a sum of squares of the differences between the parameters extracted from different frames, weighted by a regularization temperature parameter (at times herein referred to as a “temperature parameter” or “regularization parameter,” denoted by the character “2”). In traditional embodiments, this regularization temperature parameter may controls the trade-off between fitting (or calibrating to) the individual frames well and keeping the parameters similar across frames. For instance, a high value for a regularization parameter will strongly penalize variations in parameters across frames, pushing the optimization towards a single, similar end model for all frames. Conversely, a low value for a regularization parameter will allow more flexibility in fitting (or calibrating to) individual frames but may result in different end models for each frame.

Thus, in practice, such a regularization term, and parameter can be tuned to create varying DOFs within the model. If the regularization term is high, such an implementation may encourage the calibrated frame models 410A-N to approach a single, final model 474A-N (as seen in FIG. 4). If the regularization term is low, such models may fall somewhere in between the creation of a single final model, and the creation of 410A-N amount of individual models, as the models may converge along a gradient path. So to, the DOFs within the composite model may depend on the regularization term.

FIG. 5 illustrates an example multi-model co-optimization calibration strategy of FIG. 3C, according to some embodiments of the present disclosure.

In embodiments, a multi-model calibration strategy 500 can include elements of static calibration, a co-optimization component (e.g., optimizer 540), and a secondary model (e.g., simulation engine 530). Thus, in embodiments, the multi-model calibration strategy of FIG. 5 may at times be referred to as a multi-model, with co-optimization (as will be further described below).

In embodiments, calibration strategy 500 may begin with establishing a model to be applied via a modified static calibration, as well as establishing floating parameters 514 and common parameters 516 (either through hybrid or sequential calibration as seen in FIG. 4, or based on process knowledge).

In embodiments, any of the models described above with respect to FIG. 3A may be used. In embodiments, any of the models capable of function with a static (e.g., frame-wise) calibration strategy can be used. Thus, in embodiments, the primary model utilized by calibration strategy 500 may be a composite model 520 including frame models 520A-N. Individual frame models of composite model 520 may any feasible model described above with respect to FIG. 3A.

As mentioned, in embodiments, floating parameters 514 and common parameters 516 may be established from process knowledge, or from historical data gathered for a specific process. After floating parameters 514 and common parameters 516 have been established, an iterative training, or calibration, process may begin for frame models 520A-N, to adjust the floating parameters 514 and common parameters 516.

In embodiments, the iterative training process can include using a pre-trained simulation engine 530 (e.g., an RCWA engine) to generate simulated spectral values 532 from the unique parameters of each frame model. For example, in embodiments, a rigorous coupled-wave analysis simulation engine 530 may have been previously validated and refined to generate spectral values based on parameters. Thus, the simulation engine may generate unique spectral values 532, based on the active parameters of each frame model. In alternate embodiments, a different type of trained and validated deterministic model may be used.

Afterwards, each simulated spectral value 532A-N may be compared to actual, or experimental, spectral values 534A-N that the models may seek to be calibrated to. For example, optimizer 540 may apply an optimization process (e.g., a calibration process) to the parameters of composite model 520. In embodiments, optimizer 540 may correspond or be any of the optimization strategies or regimes discussed with respect to FIG. 3C. E.g., optimizer 540 may employ SGD, MCMC, ADAM, etc., to iteratively adjust the floating parameters within composite model 520. In embodiments, optimizer 540 may include any of the forms of regularization (or forego such regularization components and terms), as previously discussed.

In embodiments, optimizer 540 may utilize a loss function to quantify the difference between the simulated and experimental spectral values, and apply backpropagation and an optimization function (as was described with respect to FIG. 3C) to create slight adjustments to floating parameters 514 and/or common parameters 516. Each iterative adjustment to floating parameters 514 and/or common parameters 516 may generate increasingly accurate simulated spectral values for each model.

In embodiments, iterative training with optimizer 540 may cease once a sufficient accuracy is reached, as may be determined by a user, technician, function, or accuracy metric. Once composite model 520 has been sufficiently trained, the floating and common parameters may then be extracted. In embodiments, the common parameters 516 may have remain fixed (e.g., with respect to each other) throughout such a process, thus increased the DOFs of the model-calibration pair, while maintaining cohesion across frames through the common, or non-floating parameters.

Thus calibration strategy 500 may generate a set of unique frame models, and a composite model 520, for a given process data.

FIG. 6 illustrates an example spatial-temporal calibration strategy of FIG. 3C, according to some embodiments of the present disclosure.

In embodiments, FIG. 6 illustrates a substrate 610, including multiple area segments 612, or coupons of the substrate surface area. As seen in FIG. 6, a substrate 610 may include segments 612, or segmented areas which may be arranged. In some instances, segments 612 may be in a grid formation as seen. In embodiments, a specific segment on the substrate can be denoted by segment 612[i, j], where i∈[1, N], and j∈[1, M].

In embodiments, each segment of the substrate may be processed sequentially, or separately, to generate separate process data associated with a segment. For instance, in a singular example, in the embodiment seen within FIG. 6, the lower and right-most segment 612[N, M] may be individually processed to produce process data specific to the segment, process data 602[N, M].

As illustrated, process data 602[N, M] may correspond, or be similar to, process data 202, as seen and described in FIGS. 2A-2C. As seen, process data process data 602[N, M] may incorporate and augment the embodiments described with respect to those figures.

In embodiments, process data 602[N, M] may include process time data 602A, spectral data 602B, emission wavelength data 602C, and spatial data 602D. Process time data 602A may influence, and in embodiments include, process parameters 604. As was discussed with respect to FIG. 2B, process parameters may include both process parameters and substrate characteristics, that may be a function of time.

In embodiments, spatial data 602D may indicated the spatial location of the segment 612[N, M], with respect to the substrate surface, or the additional segments. In embodiments, spatial data 602D corresponding to segment 612[N, M] may be parametrizable and able to be input into a mathematical model of a model-calibration pair as an independent variable.

As discussed, process data 602[N, M] may correspond to segment 612[N, M], and the manufacturing operation applied to it as the process data 602[N,M] is gathered. In embodiments where the same manufacturing operation or process is applied throughout the surface of substrate 610, many similar process data sets will be generated, and process data 602 can include N×M amounts of process datasets, one for each substrate segment, or coupon. Thus, in embodiments where spatial data is included, the combined process data 602 for substrate 610 may be tri-variate data, with process time data 602A, emission wavelength data 602C, and spatial data 602D as independent variable. A suitable model and calibration strategy can be selected when modeling the trivariate data.

Thus, a spatial-temporal calibration strategy may be applied to model data from all segments, from a single process, holistically. Such a model-calibration pair may present minimal DOFs, or similar DOFs as temporal calibration, since a large amount of data is being approximated holistically, and parameter inferences can apply for all datasets.

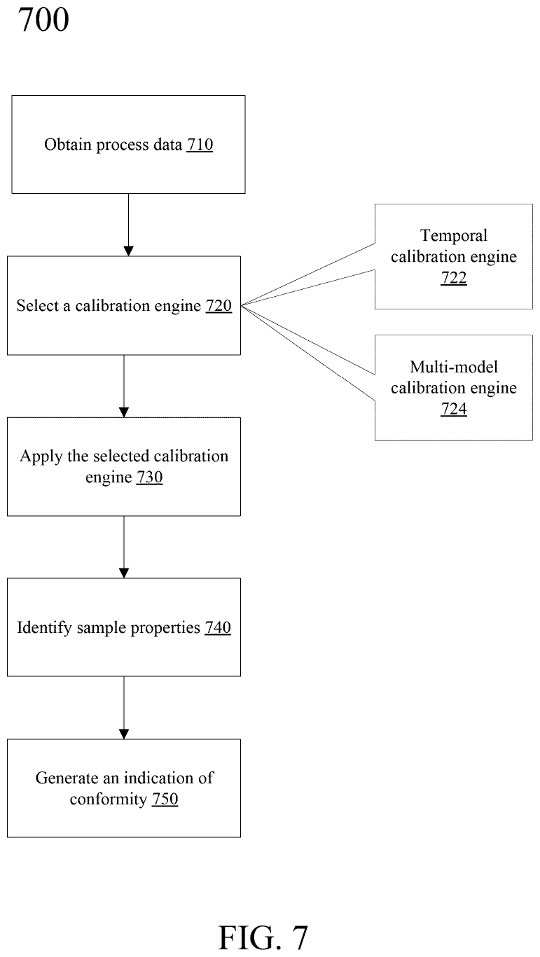

FIG. 7 illustrates a flow diagram of an example method for generating substrate parameter inferences from manufacturing sensor data, according to some embodiments of the present disclosure.

Method 700 may be performed by a processing device that may include hardware, software, or a combination of both. The processing device may include one or more central processing units (CPUs), graphics processing units (GPUs), field-programmable gate arrays (FPGAs), application-specific integrated circuits (ASICs), or the like, or any combination thereof. In one embodiment, method 700 may be performed by the OCD inference platform 130 of FIG. 1, and the associated algorithms, e.g., as described in conjunction with FIGS. 1-6. In certain embodiments, method 700 may be performed by a single processing thread. Alternatively, method 700 may be performed by two or more processing threads, each thread executing one or more individual functions, routines, subroutines, or operations of the method. In an illustrative example, the processing threads implementing method 700 may be synchronized (e.g., using semaphores, critical sections, and/or other thread synchronization mechanisms). Alternatively, the processing threads implementing method 700 may be executed asynchronously with respect to each other. Therefore, while FIG. 7 and the associated descriptions list the operations of method 700 in a certain order, in some embodiments, at least some of the described operations may be performed in parallel and/or in a different order. In some embodiments one or more operations of method 700 is not performed.

At block 710, method 700 may include obtaining process data. In some embodiments, processing logic may obtaining a plurality of sets of process data for a sample, each set of the process data associated with a respective time of a plurality of times of a sample processing operation.

At block 720, method 700 may include selecting a calibration engine. In some embodiments, the processing logic performing method 700 may select a calibration engine from a plurality of calibration engines.

As illustrated with callout block 722, the processing device performing method 700 may select a calibration engine including a temporal calibration engine. In some embodiments, processing logic may select a calibration engine including a temporal calibration engine that calibrates a joint model having one or more fitting parameters characterizing evolution of one or more sample properties across the plurality of times.

As illustrated with callout block 724, the processing device performing method 700 may select a calibration engine including a multi-model calibration engine. In some embodiments, processing logic may select a calibration engine including a multi-model calibration engine that calibrates a plurality of models, each model of the plurality of models characterizing the one or more sample properties for a respective time of the plurality of times, wherein individual models of the plurality of models are calibrated using multiple sets of the process data of the plurality of sets of process data.

At block 730, method 700 may include applying the selected calibration engine. In some embodiments, processing logic may apply the selected calibration engine to the plurality of sets of the process data to calibrate one or more models for the process data

At block 740, method 700 may include identifying sample properties. In some embodiments, processing logic may identify, using the one or more calibrated models, the one or more sample properties

At block 750, method 700 may include generating an indication of conformity. In some embodiments, processing logic may generate, in view of the one or more identified sample properties, an indication of conformity of the processing operation to a target specification.

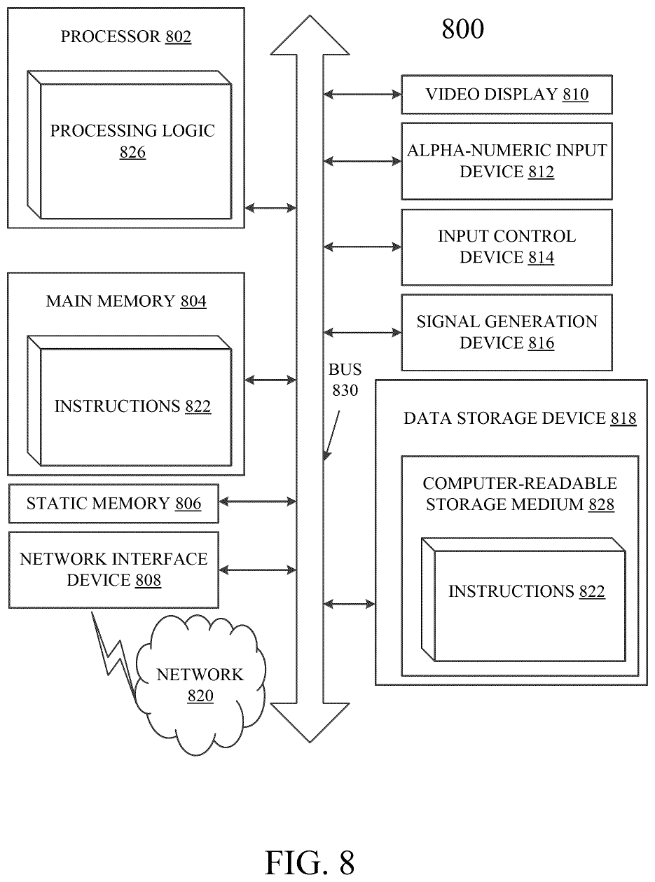

FIG. 8 illustrates a block diagram of an example processing device operating in accordance with one or more aspects of the present disclosure.

In one implementation, the processing device 800 may be a part of any computing device of FIG. 1, or any combination thereof. Example processing device 800 may be connected to other processing devices in a LAN, an intranet, an extranet, and/or the Internet. The processing device 800 may be a personal computer (PC), a set-top box (STB), a server, a network router, switch or bridge, or any device capable of executing a set of instructions (sequential or otherwise) that specify actions to be taken by that device. Further, while only a single example processing device is illustrated, the term “processing device” shall also be taken to include any collection of processing devices (e.g., computers) that individually or jointly execute a set (or multiple sets) of instructions to perform any one or more of the methods discussed herein.

Example processing device 800 may include a processor 802 (e.g., a CPU), a main memory 804 (e.g., read-only memory (ROM), flash memory, dynamic random access memory (DRAM) such as synchronous DRAM (SDRAM), etc.), a static memory 806 (e.g., flash memory, static random access memory (SRAM), etc.), and a secondary memory (e.g., a data storage device 818), which may communicate with each other via a bus 830.

Processor 802 represents one or more general-purpose processing devices such as a microprocessor, central processing unit, or the like. More particularly, processor 802 may be a complex instruction set computing (CISC) microprocessor, reduced instruction set computing (RISC) microprocessor, very long instruction word (VLIW) microprocessor, processor implementing other instruction sets, or processors implementing a combination of instruction sets. Processor 802 may also be one or more special-purpose processing devices such as an application specific integrated circuit (ASIC), a field programmable gate array (FPGA), a digital signal processor (DSP), network processor, or the like. In accordance with one or more aspects of the present disclosure, processor 802 may be configured to execute instructions (e.g. processing logic 826 may implement predictive module 132 of FIG. 1).

Example processing device 800 may further include a network interface device 808, which may be communicatively coupled to a network 820. Example processing device 800 may further comprise a video display 810 (e.g., a liquid crystal display (LCD), a touch screen, or a cathode ray tube (CRT)), an alphanumeric input device 812 (e.g., a keyboard), an input control device 814 (e.g., a cursor control device, a touch-screen control device, a mouse), and a signal generation device 816 (e.g., an acoustic speaker).

Data storage device 818 may include a computer-readable storage medium (or, more specifically, a non-transitory computer-readable storage medium) 828 on which is stored one or more sets of executable instructions 822. In accordance with one or more aspects of the present disclosure, executable instructions 822 may comprise executable instructions (e.g. implementing predictive module 132 of FIG. 1).

Executable instructions 822 may also reside, completely or at least partially, within main memory 804 and/or within processor 802 during execution thereof by example processing device 800, main memory 804 and processor 802 also constituting computer-readable storage media. Executable instructions 822 may further be transmitted or received over a network via network interface device 808.

While the computer-readable storage medium 828 is shown in FIG. 8 as a single medium, the term “computer-readable storage medium” should be taken to include a single medium or multiple media (e.g., a centralized or distributed database, and/or associated caches and servers) that store the one or more sets of operating instructions. The term “computer-readable storage medium” shall also be taken to include any medium that is capable of storing or encoding a set of instructions for execution by the machine that cause the machine to perform any one or more of the methods described herein. The term “computer-readable storage medium” shall accordingly be taken to include, but not be limited to, solid-state memories, and optical and magnetic media.

It should be understood that the above description is intended to be illustrative, and not restrictive. Many other embodiment examples will be apparent to those of skill in the art upon reading and understanding the above description. Although the present disclosure describes specific examples, it will be recognized that the systems and methods of the present disclosure are not limited to the examples described herein, but may be practiced with modifications within the scope of the appended claims. Accordingly, the specification and drawings are to be regarded in an illustrative sense rather than a restrictive sense. The scope of the present disclosure should, therefore, be determined with reference to the appended claims, along with the full scope of equivalents to which such claims are entitled.

The embodiments of methods, hardware, software, firmware, or code set forth above may be implemented via instructions or code stored on a machine-accessible, machine readable, computer accessible, or computer readable medium which are executable by a processing element. “Memory” includes any mechanism that provides (i.e., stores and/or transmits) information in a form readable by a machine, such as a computer or electronic system. For example, “memory” includes random-access memory (RAM), such as static RAM (SRAM) or dynamic RAM (DRAM); ROM; magnetic or optical storage medium; flash memory devices; electrical storage devices; optical storage devices; acoustical storage devices, and any type of tangible machine-readable medium suitable for storing or transmitting electronic instructions or information in a form readable by a machine (e.g., a computer).

Reference throughout this specification to “one embodiment” or “an embodiment” means that a particular feature, structure, or characteristic described in connection with the embodiment is included in at least one embodiment of the disclosure. Thus, the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments.

In the foregoing specification, a detailed description has been given with reference to specific exemplary embodiments. It will, however, be evident that various modifications and changes may be made thereto without departing from the broader spirit and scope of the disclosure as set forth in the appended claims. The specification and drawings are, accordingly, to be regarded in an illustrative sense rather than a restrictive sense. Furthermore, the foregoing use of embodiment, embodiment, and/or other exemplarily language does not necessarily refer to the same embodiment or the same example, but may refer to different and distinct embodiments, as well as potentially the same embodiment.

The words “example” or “exemplary” are used herein to mean serving as an example, instance, or illustration. Any aspect or design described herein as “example” or “exemplary” is not necessarily to be construed as preferred or advantageous over other aspects or designs. Rather, use of the words “example” or “exemplary” is intended to present concepts in a concrete fashion. As used in this application, the term “or” is intended to mean an inclusive “or” rather than an exclusive “or.” That is, unless specified otherwise, or clear from context, “X includes A or B” is intended to mean any of the natural inclusive permutations. That is, if X includes A; X includes B; or X includes both A and B, then “X includes A or B” is satisfied under any of the foregoing instances. In addition, the articles “a” and “an” as used in this application and the appended claims should generally be construed to mean “one or more” unless specified otherwise or clear from context to be directed to a singular form. Moreover, use of the term “an embodiment” or “one embodiment” or “an embodiment” or “one embodiment” throughout is not intended to mean the same embodiment or embodiment unless described as such. Also, the terms “first,” “second,” “third,” “fourth,” etc. as used herein are meant as labels to distinguish among different elements and may not necessarily have an ordinal meaning according to their numerical designation.

A digital computer program, which may also be referred to or described as a program, software, a software application, a module, a software module, a script, or code, can be written in any form of programming language, including compiled or interpreted languages, or declarative or procedural languages, and it can be deployed in any form, including as a stand-alone program or as a module, component, subroutine, or other unit suitable for use in a digital computing environment. The essential elements of a digital computer a central processing unit for performing or executing instructions and one or more memory devices for storing instructions and digital data. The central processing unit and the memory can be supplemented by, or incorporated in, special purpose logic circuitry or quantum simulators. Generally, a digital computer will also include, or be operatively coupled to receive digital data from or transfer digital data to, or both, one or more mass storage devices for storing digital data, e.g., magnetic, magneto-optical disks, optical disks, or systems suitable for storing information. However, a digital computer need not have such devices.

Digital computer-readable media suitable for storing digital computer program instructions and digital data include all forms of non-volatile digital memory, media, and memory devices, including by way of example semiconductor memory devices, e.g., EPROM, EEPROM, and flash memory devices; magnetic disks, e.g., internal hard disks or removable disks; magneto-optical disks; CD-ROM and DVD-ROM disks.

Control of the various systems described in this specification, or portions of them, can be implemented in a digital computer program product that includes instructions that are stored on one or more non-transitory machine-readable storage media, and that are executable on one or more digital processing devices. The systems described in this specification, or portions of them, can each be implemented as an apparatus, method, or system that may include one or more digital processing devices and memory to store executable instructions to perform the operations described in this specification.

While this specification contains many specific embodiment details, these should not be construed as limitations on the scope of what may be claimed, but rather as descriptions of features that may be specific to particular embodiments. Certain features that are described in this specification in the context of separate embodiments can also be implemented in combination in a single embodiment. Conversely, various features that are described in the context of a single embodiment can also be implemented in multiple embodiments separately or in any suitable sub-combination. Moreover, although features may be described above as acting in certain combinations and even initially claimed as such, one or more features from a claimed combination can in some cases be excised from the combination, and the claimed combination may be directed to a sub-combination or variation of a sub-combination.

Similarly, while operations are depicted in the drawings in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system modules and components in the embodiments described above should not be understood as requiring such separation in all embodiments, and it should be understood that the described program components and systems can generally be integrated together in a single software product or packaged into multiple software products.

Particular embodiments of the subject matter have been described. Other embodiments are within the scope of the following claims. For example, the actions recited in the claims can be performed in a different order and still achieve desirable results. As one example, the processes depicted in the accompanying figures do not necessarily require the particular order shown, or sequential order, to achieve desirable results. In some cases, multitasking and parallel processing may be advantageous.

1. A method comprising:
obtaining a plurality of sets of process data for a sample, each set of the process data associated with a respective time of a plurality of times of a sample processing operation;
selecting a calibration engine from a plurality of calibration engines, wherein the plurality of calibration engines comprises at least:
a temporal calibration engine that calibrates a joint model having one or more fitting parameters characterizing evolution of one or more sample properties across the plurality of times; and
a multi-model calibration engine that calibrates a plurality of models, each model of the plurality of models characterizing the one or more sample properties for a respective time of the plurality of times, wherein individual models of the plurality of models are calibrated using multiple sets of the process data of the plurality of sets of process data;
applying the selected calibration engine to the plurality of sets of the process data to calibrate one or more models for the process data;
identifying, using the one or more calibrated models, the one or more sample properties; and
generating, in view of the one or more identified sample properties, an indication of conformity of the processing operation to a target specification.

2. The method of claim 1, wherein the plurality of calibration engines further comprises a frame-wise calibration engine that calibrates a set of independent models, each independent model of the set of independent models characterizing the one or more sample properties for a corresponding time of the plurality of times, wherein each independent model is calibrated using a set of the process data associated with the corresponding time of the plurality of times.

3. The method of claim 1, wherein to calibrate the plurality of models, the multi-model calibration engine is to perform operations comprising:
causing the temporal calibration engine to generate the joint model;
obtaining a plurality of seed models, each seed model of the plurality of seed models having the one or more sample properties determined, for a corresponding time of the plurality of times, using the one or more fitting parameters of the joint model; and
modifying the plurality of seed models to obtain the plurality of models, each model of the plurality of models modified using a set of the process data associated with the corresponding time of the plurality of times.

4. The method of claim 3, wherein modifying the plurality of seed models to obtain the plurality of models comprises:
using a loss function that comprises one or more regularization terms that disfavor fluctuations of the one or more sample properties across the plurality of models.

5. The method of claim 1, wherein to calibrate the plurality of models, the multi-model calibration engine is to perform operations comprising:
identifying one or more common sample properties that remain constant over the plurality of times;
causing the temporal calibration engine to generate the joint model comprising the common sample properties;
obtaining, a plurality of initial models, each initial model of the plurality of initial models having one or more varying sample properties determined, for a corresponding time of the plurality of times, using the one or more fitting parameters of the joint model; and
modifying the plurality of initial models to obtain the plurality of models.

6. The method of claim 5, wherein modifying the plurality of initial models to obtain the plurality of models comprises:
modifying the one or more common sample properties uniformly across the plurality of models; and
modifying the one or more varying sample properties individually across the plurality of models.

7. The method of claim 6, wherein modifying the one or more varying sample properties across the plurality of models is subject to a loss function that comprises one or more regularization terms that disfavor variations of the varying sample properties across the plurality of models.

8. The method of claim 1, wherein the plurality of calibration engines further comprises:
a relaxed temporal calibration engine that calibrates a joint model characterizing evolution of one or more sample properties across the plurality of times subject to a constraint that the one or more sample properties have a spline behavior across the plurality of times.

9. The method of claim 1, wherein the one or more identified sample properties comprise one or more dimensions of the sample.

10. The method of claim 1, wherein the process data comprises optical inspection data for the sample.

11. The method of claim 1, wherein each set of the process data associated with the respective time of the plurality of times comprises a plurality of sets of spatial data collected for each of a plurality of spatial regions at the respective time of the plurality of times.

12. The method of claim 1, wherein a first sample property of the one or more sample properties is identified using a first calibrated model of the one or more models, the first calibrated model calibrated using the temporal calibration engine, and wherein a second sample property of the one or more sample properties is identified using a second calibrated model of the one or more models, the second calibrated model calibrated using the multi-model calibration engine.

13. A system, comprising memory and a processing device coupled to the memory, wherein the processing device is to:
obtain a plurality of sets of process data for a sample, each set of the process data associated with a respective time of a plurality of times of a sample processing operation;
select a calibration engine from a plurality of calibration engines, wherein the plurality of calibration engines comprises at least:
a temporal calibration engine that calibrates a joint model having one or more fitting parameters characterizing evolution of one or more sample properties across the plurality of times; and
a multi-model calibration engine that calibrates a plurality of models, each model of the plurality of models characterizing the one or more sample properties for a respective time of the plurality of times, wherein individual models of the plurality of models are calibrated using multiple sets of the process data of the plurality of sets of process data;
apply the selected calibration engine to the plurality of sets of the process data to calibrate one or more models for the process data;
identify, using the one or more calibrated models, the one or more sample properties; and
generate, in view of the one or more identified sample properties, an indication of conformity of the processing operation to a target specification.

14. The system of claim 13, wherein to calibrate the plurality of models, the multi-model calibration engine is to:
cause the temporal calibration engine to generate the joint model;
obtain a plurality of seed models, each seed model of the plurality of seed models having the one or more sample properties determined, for a corresponding time of the plurality of times, using the one or more fitting parameters of the joint model; and
modify the plurality of seed models to obtain the plurality of models, each model of the plurality of models modified using a set of the process data associated with the corresponding time of the plurality of times.

15. The system of claim 14, wherein to modify the plurality of seed models to obtain the plurality of models, the multi-model calibration engine is to:
use a loss function that comprises one or more regularization terms that disfavor fluctuations of the one or more sample properties across the plurality of models.

16. The system of claim 13, wherein to calibrate the plurality of models, the multi-model calibration engine is to:
identify one or more common sample properties that remain constant over the plurality of times;
cause the temporal calibration engine to generate the joint model comprising the common sample properties;
obtain, a plurality of initial models, each initial model of the plurality of initial models having one or more varying sample properties determined, for a corresponding time of the plurality of times, using the one or more fitting parameters of the joint model; and
modify the plurality of initial models to obtain the plurality of models.

17. The system of claim 16, wherein to modify the plurality of initial models, the multi-model calibration engine is to:
modify the one or more common sample properties uniformly across the plurality of models; and
modify the one or more varying sample properties individually across the plurality of models.

18. The system of claim 17, wherein to modify the one or more varying sample properties across the plurality of models, the multi-model calibration engine is to use a loss function that comprises one or more regularization terms that disfavor variations of the varying sample properties across the plurality of models.

19. The system of claim 13, wherein each set of the process data associated with the respective time of the plurality of times comprises a plurality of sets of spatial data collected for each of a plurality of spatial regions at the respective time of the plurality of times.

20. A non-transitory computer readable storage medium comprising instructions that, when executed by a processing device, causes the processing device to perform operations comprising:
obtaining a plurality of sets of process data for a sample, each set of the process data associated with a respective time of a plurality of times of a sample processing operation;
selecting a calibration engine from a plurality of calibration engines, wherein the plurality of calibration engines comprises at least:
a temporal calibration engine that calibrates a joint model having one or more fitting parameters characterizing evolution of one or more sample properties across the plurality of times; and
a multi-model calibration engine that calibrates a plurality of models, each model of the plurality of models characterizing the one or more sample properties for a respective time of the plurality of times, wherein individual models of the plurality of models are calibrated using multiple sets of the process data of the plurality of sets of process data;
applying the selected calibration engine to the plurality of sets of the process data to calibrate one or more models for the process data;
identifying, using the one or more calibrated models, the one or more sample properties; and
generating, in view of the one or more identified sample properties, an indication of conformity of the processing operation to a target specification.
